(19) United States
(12) Patent Application Publication
(10) Pub. No.: US 2026/0341384 A1
(43) Pub. Date: Oct. 29, 2026

(54) PRE-WRITE OPEN BLOCK READ LOOK AHEAD DETECTION ALGORITHM

(71) Applicant: Sandisk Technologies, Inc., Milpitas, CA (US)

(72) Inventors: Zhenni Wan, San Jose, CA (US); Jia Li, San Francisco, CA (US); Bo Lei, San Jose, CA (US)

(21) Appl. No.: 19/193,252

(22) Filed: Apr. 29, 2025

(51) Int. Cl. G11C 29/12

(52) U.S. Cl. CPC G11C 29/12005; G11C 2029/1202

(57) ABSTRACT

A memory apparatus includes memory cells connected to word lines and configured to retain a threshold voltage. The memory cells are disposed in memory holes grouped into blocks. A control means is configured to read and count a data mismatch count of the memory cells connected to a predetermined one of the word lines of one of the blocks having the threshold voltage greater than a predetermined read threshold voltage in response to an open block read disturb detection operation being triggered prior to data being programmed to the memory cells of the one of the blocks. The control means is also configured to stop programming the memory cells of the one of the blocks and relocate the data to another one of the blocks in response to the data mismatch count being greater than a predetermined mismatch threshold.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory is widely used in various electronic devices such as cellular telephones, digital cameras, personal digital assistants, medical electronics, mobile computing devices, non-mobile computing devices and data servers. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory), Electrically Erasable Programmable Read-Only Memory (EEPROM), and others.

When a memory system is deployed in or connected to an electronic device (the host), the memory system can be used to store data and read data. It is important that writing and reading is performed accurately, so that data is not lost. Over time the integrity of the stored data may suffer due to effects such as read disturb. Read disturb is a phenomenon in which reading memory cells disturbs the data stored in either the read data cells or other data cells not presently being read. Effects such as read disturb can cause what is referred to as a failed bit. A failed bit means that a value of a bit that is read is flipped from the value that was stored. The memory system is able to correct for some of the failed bits by use of an error correction algorithm, which is used to decode the data.

Read scrub is a technique that re-writes data from time to time, with a goal of re-writing the data prior to the data integrity becoming so poor that the data cannot be successfully decoded. One read scrub technique is to read the data, use an error correction algorithm to correct any failed bits (or flipped bits) in the data, and then re-write the data. The data could be re-written to a different location than the location from which it was read and flag potentially problematic memory cells. Nevertheless, some memory cells may not be flagged by the read scrub for various reasons.

### SUMMARY

This section provides a general summary of the present disclosure and is not a comprehensive disclosure of its full scope or all of its features and advantages.

An object of the present disclosure is to provide a memory apparatus and a method of operation of the memory apparatus that address and overcome shortcomings described herein.

Accordingly, it is an aspect of the present disclosure to provide a memory apparatus including memory cells each connected to one of a plurality of word lines. The memory cells are disposed in memory holes and grouped into a plurality of blocks. The memory cells are configured to retain a threshold voltage. The memory apparatus also includes a control means configured to read and count a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks. The control means is also configured to stop programming the memory cells of the one of the plurality of blocks and relocate the data to another one of the plurality of blocks in response to the data mismatch count being greater than a predetermined mismatch threshold.

According to another aspect of the disclosure, a controller in communication with a memory apparatus including memory cells each connected to one of a plurality of word lines is provided. The memory cells are disposed in memory holes and grouped into a plurality of blocks. The memory cells are configured to retain a threshold voltage. The controller is configured to instruct the memory apparatus to read and count a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks. The controller is also configured to instruct the memory apparatus to stop programming the memory cells of the one of the plurality of blocks and relocate the data to another one of the plurality of blocks in response to the data mismatch count being greater than a predetermined mismatch threshold.

According to an additional aspect of the disclosure, a method of operating a memory apparatus is provided. The memory apparatus includes memory cells each connected to one of a plurality of word lines. The memory cells are disposed in memory holes and grouped into a plurality of blocks. The memory cells are configured to retain a threshold voltage. The method includes the step of reading and counting a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks. The method also includes the step of stopping programming the memory cells of the one of the plurality of blocks and relocating the data to another one of the plurality of blocks in response to the data mismatch count being greater than a predetermined mismatch threshold.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

For a detailed description of example embodiments, reference will now be made to the accompanying drawings in which:

FIG. 1A is a block diagram of one embodiment of a memory system connected to a host according to aspects of the disclosure;

FIG. 1B is a block diagram of one embodiment of a Front End Processor Circuit according to aspects of the disclosure;

FIG. 1C is a block diagram of one embodiment of a Back End Processor Circuit according to aspects of the disclosure;

FIG. 1D is a block diagram of one embodiment of a memory package according to aspects of the disclosure;

FIG. 2 is a block diagram of one embodiment of a memory die according to aspects of the disclosure;

FIG. 3 is a perspective view of a portion of one embodiment of a monolithic three dimensional memory structure.

FIG. 4A is a block diagram of a memory structure having two planes according to aspects of the disclosure;

FIG. 4B depicts a top view of a portion of a block of memory cells according to aspects of the disclosure;

FIG. 4C depicts a cross sectional view of a portion of a block of memory cells according to aspects of the disclosure;

FIG. 4D depicts a view of the select gate layers and word line layers according to aspects of the disclosure;

FIG. 4E is a cross sectional view of a vertical column of memory cells according to aspects of the disclosure;

FIG. 4F depicts a cross section (in an x-y plane) of memory hole 432 of FIG. 4E according to aspects of the disclosure;

FIG. 4G is a schematic of a plurality of NAND strings according to aspects of the disclosure;

FIG. 5 depicts threshold voltage distributions according to aspects of the disclosure;

FIG. 6 is a table describing one example of an assignment of data values to data states according to aspects of the disclosure;

FIG. 7 is a flow chart describing one embodiment of a process for programming according to aspects of the disclosure;

FIG. 8 is a flowchart of one embodiment of a process of reading non-volatile memory cells according to aspects of the disclosure;

FIG. 9 shows three NAND strings of a block of memory cells implementing the process of FIG. 8 according to aspects of the disclosure;

FIG. 10 shows an example plot of fail bit count (FBC) versus word line according to aspects of the disclosure;

FIG. 11 is a flowchart of one embodiment of a read scrub according to aspects of the disclosure;

FIG. 12 depicts an example of a memory hole that tapers according to aspects of the disclosure;

FIG. 13 depicts another example of a memory hole formed of two tiers that each taper and illustrates read disturb risk regions according to aspects of the disclosure;

FIG. 14 shows a plot of the failure bit count versus logical word line for various read disturb scenarios according to aspects of the disclosure;

FIG. 15 shows a block with some erased word lines and fewer programmed word lines along with a plot showing a corresponding erase upper tail upshift with a read disturb risk region according to aspects of the disclosure;

FIG. 16 is a plot of failure bit count versus read disturb count according to aspects of the disclosure;

FIG. 17 shows a first view of a block with some erased word lines and fewer programmed word lines along with a plot showing a corresponding erase upper tail upshift in an upper portion and a second view of the block during a program operation in which the open block read disturb detection operation is triggered, high data mismatch count on the predetermined one of the plurality of word lines, and the data of the block relocated along with a plot showing the threshold voltage distribution of the erased state and the A or S1 data state after heavy read disturb in a lower portion according to aspects of the disclosure; and

FIGS. 18-20 illustrate steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of forming of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Various terms are used to refer to particular system components. Different companies may refer to a component by different names-this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

Additionally, when a layer or element is referred to as being “on” another layer or substrate, in can be directly on the other layer of substrate, or intervening layers may also be present. Further, it will be understood that when a layer is referred to as being “under” another layer, it can be directly under, and one or more intervening layers may also be present. Furthermore, when a layer is referred to as “between” two layers, it can be the only layer between the two layers, or one or more intervening layers may also be present.

For purposes of this document, reference in the specification to “an embodiment,” “one embodiment,” “some embodiments,” or “another embodiment” may be used to describe different embodiments or the same embodiment.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The terms “logical block” and “physical block” will be used herein. Each logical block has a logical block address (LBA). Each physical block has a physical block address (PBA). The memory system keeps a mapping between logical blocks and physical blocks, in some embodiments. The mapping between logical blocks and physical blocks may change over time. For example, the data for a logical block may be moved from one physical block to another physical block. As one particular example, when read scrub is performed the data for a logical block may be read from one physical block, any failed bits corrected, and then the corrected data may be written to another physical block. After a read scrub, the logical block address remains the same, but the physical block address changes, in some embodiments. Note that it is possible to re-write the data in place, in which case the PBA will not change after a read scrub. Thus, a physical block refers to the physical memory cells in which the data is stored. A logical block address may be thought of as an abstraction that allows the memory system to keep a consistent memory address for a host even though the physical location of the data may change.

A high read intensive block is defined herein with respect to the logical blocks, in some embodiments. A high read intensive block is defined herein as a logical block for which the read intensity is greater than a threshold. Read intensity is based on the number to reads of the physical block(s) associated with the logical block.

As described, non-volatile memory systems are a type of memory that retains stored information without requiring an external power source. Non-volatile memory is widely used in various electronic devices and in stand-alone memory devices. For example, non-volatile memory can be found in laptops, digital audio player, digital cameras, smart phones, video games, scientific instruments, industrial robots, medical electronics, solid-state drives, USB drives, memory cards, and the like. Non-volatile memory can be electronically programmed/reprogrammed and erased.

Examples of non-volatile memory systems include flash memory, such as NAND flash or NOR flash. NAND flash memory structures typically arrange multiple memory cell transistors (e.g., floating-gate transistors or charge trap transistors) in series with and between two select gates (e.g., a drain-side select gate and a source-side select gate). The memory cell transistors in series and the select gates may be referred to as a NAND string. NAND flash memory may be scaled in order to reduce cost per bit.

A programming operation for a set of memory cells of a memory device typically involves applying a series of program voltages to the memory cells after the memory cells are provided in an erased state. Each program voltage is provided in a program loop, also referred to as a program-verify iteration. For example, the program voltage may be applied to a word line which is connected to control gates of the memory cells. In one approach, incremental step pulse programming is performed, where the program voltage is increased by a step size in each program loop. Verify operations may be performed after each program voltage to determine whether the memory cells have completed programming. When programming is completed for a memory cell, it can be locked out from further programming while programming continues for other memory cells in subsequent program loops.

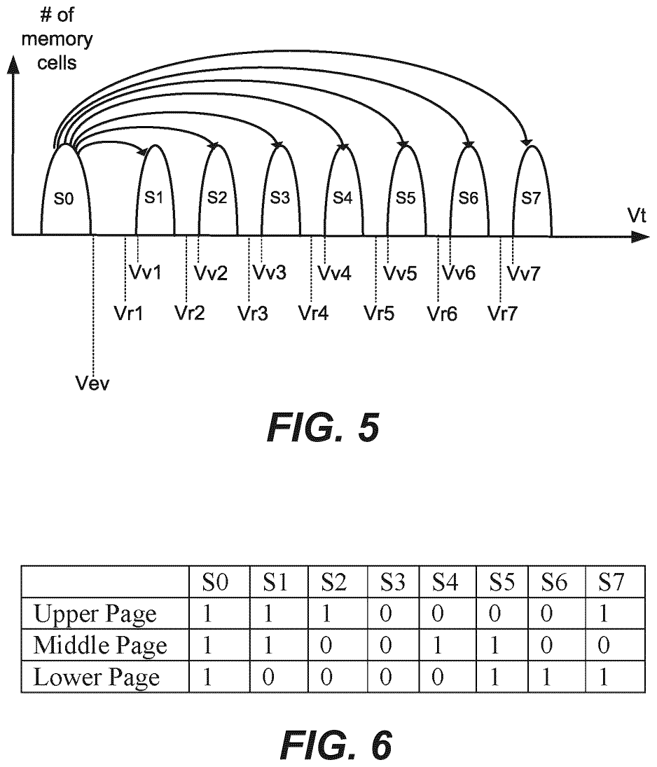

Each memory cell may be associated with a data state according to write data in a program command. Based on its data state, a memory cell will either remain in the erased state or be programmed to a data state (a programmed data state) different from the erased state. For example, in a one-bit per cell memory device (single-level cell (SLC)), there are two data states including the erased state and one higher data state. In a two-bit per cell memory device (multi-level cell (MLC)), there are four data states including the erased state and three higher data states referred to as the A, B and C data states. In a three-bit per cell memory device (triple-level cell (TLC)), there are eight data states including the erased or S0 state and seven higher data states referred to as the A, B, C, D, E, F and G data states or S1, S2, S3, S4, S5, S6, S7 (see FIG. 5). In a four-bit per cell memory device (quad-level cell (QLC)), there are sixteen data states including the erased state and fifteen higher data states referred to as the Er, S1, S2, S3, S4, S5, S6, S7, S8, S9, S10, S11, S12, S13, S14, S15 data states. Each memory cell may store a data state (e.g., a binary value) and is programmed to a threshold voltage state corresponding to the data state. Each state represents a different value and is assigned a voltage window including a range of possible threshold voltages.

The memory cells of written blocks may be periodically read to check for failed bits due to read disturb (RD), for example, as part of a read patrol operation. Such read patrol operation is necessary to help flag failing blocks to help prevent data loss when failing blocks are used. Nevertheless various factors may cause some blocks to not be flagged by the read patrol after heavy read disturb.

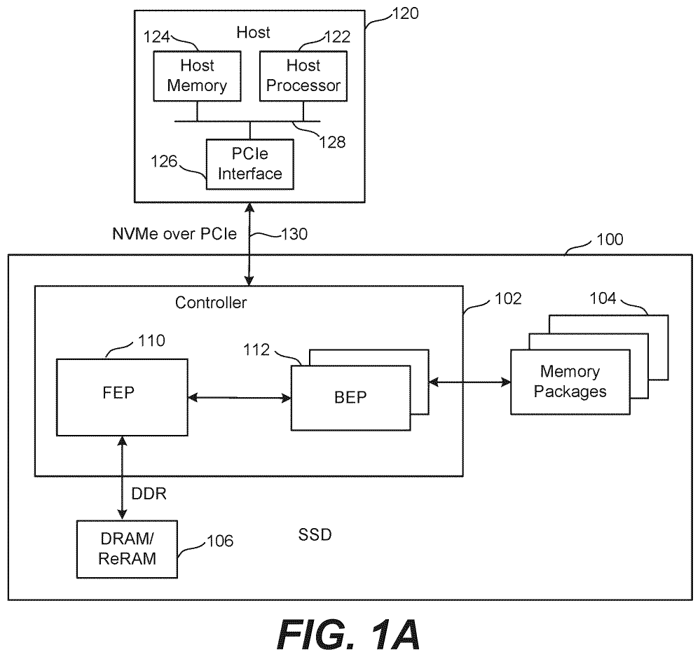

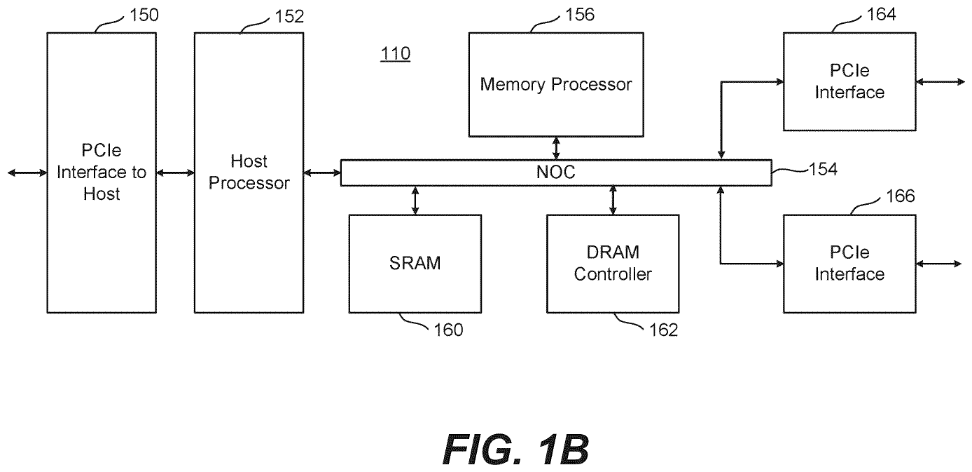

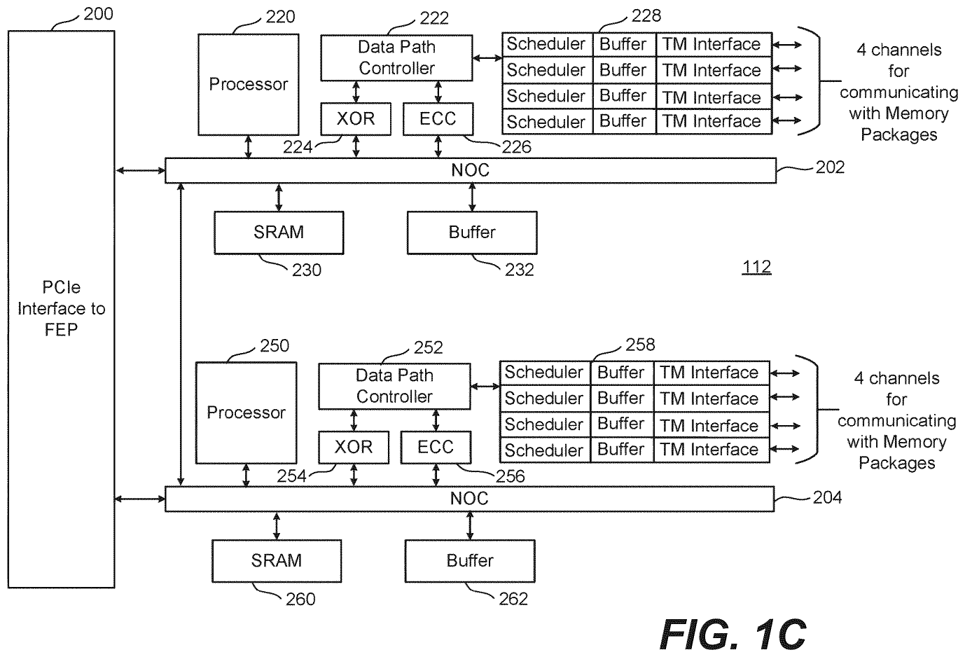

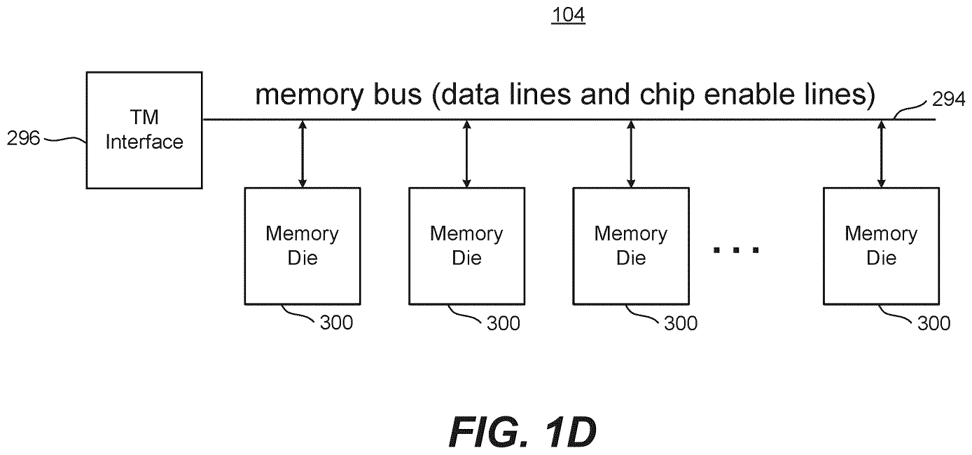

FIG. 1A is a block diagram of one embodiment of a memory system 100 connected to a host 120. Memory system 100 can implement the technology proposed herein. Many different types of memory systems can be used with the technology proposed herein. One example memory system is a solid state drive (“SSD”); however, other types of memory systems can also be used. Memory system 100 comprises a Controller 102, non-volatile memory 104 for storing data, and local memory (e.g. DRAM/ReRAM) 106. Controller 102 comprises a Front End Processor Circuit (FEP) 110 and one or more Back End Processor Circuits (BEP) 112. In one embodiment FEP110 circuit is implemented on an ASIC. In one embodiment, each BEP circuit 112 is implemented on a separate ASIC. The ASICs for each of the BEP circuits 112 and the FEP circuit 110 are implemented on the same semiconductor such that the Controller 102 is manufactured as a System on a Chip (“SoC”). FEP 110 and BEP 112 both include their own processors. In one embodiment, FEP110 and BEP 112 work as a master slave configuration where the FEP110 is the master and each BEP 112 is a slave. For example, FEP circuit 110 implements a flash translation layer that performs memory management (e.g., garbage collection, wear leveling, etc.), logical to physical address translation, communication with the host, management of DRAM (local volatile memory) and management of the overall operation of the SSD (or other non-volatile storage system). The BEP circuit 112 manages memory operations in the memory packages/die at the request of FEP circuit 110. For example, the BEP circuit 112 can carry out the read, erase and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages. Controller 102 is one example of a control circuit.

In one embodiment, non-volatile memory 104 comprises a plurality of memory packages. Each memory package includes one or more memory die. Therefore, Controller 102 is connected to one or more non-volatile memory die. In one embodiment, each memory die in the memory packages 14 utilize NAND flash memory (including two dimensional NAND flash memory and/or three dimensional NAND flash memory). In other embodiments, the memory package can include other types of memory.

Controller 102 communicates with host 120 via an interface 130 that implements NVM Express (NVMe) over PCI Express (PCIe). For working with memory system 100, host 120 includes a host processor 122, host memory 124, and a PCIe interface 126 connected to bus 128. Host memory 124 is the host's physical memory, and can be DRAM, SRAM, non-volatile memory or another type of storage. Host 120 is external to and separate from memory system 100. In one embodiment, memory system 100 is embedded in host 120.

FIG. 1B is a block diagram of one embodiment of FEP circuit 110. FIG. 1B shows a PCIe interface 150 to communicate with host 120 and a host processor 152 in communication with that PCIe interface. The host processor 152 can be any type of processor known in the art that is suitable for the implementation. Host processor 152 is in communication with a network-on-chip (NOC) 154. A NOC is a communication subsystem on an integrated circuit, typically between cores in a SoC. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, SRAM 160 and a DRAM controller 162. The DRAM controller 162 is used to operate and communicate with the DRAM (e.g., DRAM 106). SRAM 160 is local RAM memory used by memory processor 156. Memory processor 156 is used to run the FEP circuit and perform the various memory operations. Also in communication with the NOC are two PCIe Interfaces 164 and 166. In the embodiment of FIG. 1B, the SSD controller will include two BEP circuits 112; therefore there are two PCIe Interfaces 164/166. Each PCIe Interface communicates with one of the BEP circuits 112. In other embodiments, there can be more or less than two BEP circuits 112; therefore, there can be more than two PCIe Interfaces.

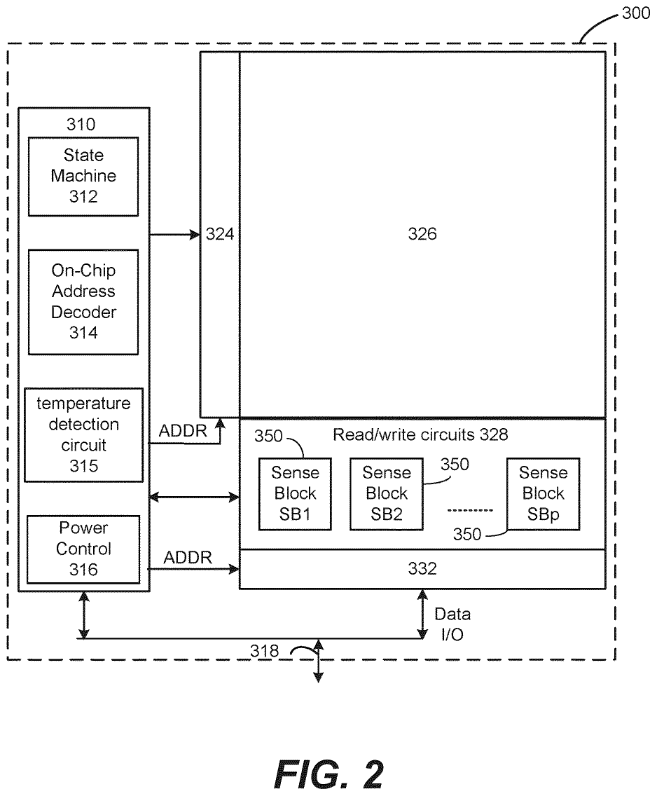

FIG. 1C is a block diagram of one embodiment of the BEP circuit 112. FIG. 1C shows a PCIe Interface 200 for communicating with the FEP circuit 110 (e.g., communicating with one of PCIe Interfaces 164 and 166 of FIG. 2). PCIe Interface 200 is in communication with two NOCs 202 and 204. In one embodiment the two NOCs can be combined to one large NOC. Each NOC (202/204) is connected to SRAM (230/260), a buffer (232/262), processor (220/250), and a data path controller (222/252) via an XOR engine (224/254) and an ECC engine (226/256). The ECC engines 226/256 are used to perform error correction, as known in the art. The XOR engines 224/254 are used to XOR the data so that data can be combined and stored in a manner that can be recovered in case there is a programming error. Data path controller 22 is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer and TM Interface for each of the channels. The processor can be any standard processor known in the art. The data path controllers 222/252 can be a processor, FPGA, microprocessor or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

FIG. 1D is a block diagram of one embodiment of a memory package 104 that includes a plurality of memory die 300 connected to a memory bus (data lines and chip enable lines) 294. The memory bus 294 connects to a Toggle Mode Interface 296 for communicating with the TM Interface of a BEP circuit 112 (see e.g., FIG. 1C). In some embodiments, the memory package can include a small controller connected to the memory bus and the TM Interface. The memory package can have one or more memory die. In one embodiment, each memory package includes eight or 16 memory die; however, other numbers of memory die can also be implemented. The technology described herein is not limited to any particular number of memory die.

FIG. 2 is a functional block diagram of one embodiment of a memory die 300. Each of the one or more memory die 300 of FIG. 1D can be implemented as memory die 300 of FIG. 2. The components depicted in FIG. 2 are electrical circuits. In one embodiment, each memory die 300 includes a memory structure 326, control circuitry 310, and read/write circuits 328, all of which are electrical circuits. Memory structure 326 is addressable by word lines via a row decoder 324 and by bit lines via a column decoder 332. The read/write circuits 328 include multiple sense blocks 350 including SB1, SB2, . . . , SBp (sensing circuitry) and allow a page (or multiple pages) of data in multiple memory cells to be read or programmed in parallel. In one embodiment, each sense block include a sense amplifier and a set of latches connected to the bit line. The latches store data to be written and/or data that has been read. The sense blocks include bit line drivers.

Commands and data are transferred between the controller and the memory die 300 via lines 318. In one embodiment, memory die 300 includes a set of input and/or output (I/O) pins that connect to lines 318.

Control circuitry 310 cooperates with the read/write circuits 328 to perform memory operations (e.g., write, read, erase, and others) on memory structure 326. In one embodiment, control circuitry 310 includes a state machine 312, an on-chip address decoder 314, a power control circuit 316 and a temperature detection circuit 315. State machine 312 provides die-level control of memory operations. In one embodiment, state machine 312 is programmable by software. In other embodiments, state machine 312 does not use software and is completely implemented in hardware (e.g., electrical circuits). In some embodiments, state machine 312 can be replaced by a microcontroller or microprocessor. In one embodiment, control circuitry 310 includes buffers such as registers, ROM fuses and other storage devices for storing default values such as base voltages and other parameters.

The on-chip address decoder 314 provides an address interface between addresses used by controller 102 to the hardware address used by the decoders 324 and 332. Power control module 316 controls the power and voltages supplied to the word lines and bit lines during memory operations. Power control module 316 may include charge pumps for creating voltages.

For purposes of this document, control circuitry 310, alone or in combination with read/write circuits 328 and decoders 324/332, comprise one or more control circuits for memory structure 326. These one or more control circuits are electrical circuits that perform the functions described below in the flow charts and signal diagrams. In other embodiments, the one or more control circuits can consist only of controller 102, which is an electrical circuit in combination with software, that performs the functions described below in the flow charts and signal diagrams. In another alternative, the one or more control circuits comprise controller 102 and control circuitry 310 performing the functions described below in the flow charts and signal diagrams. In another embodiment, the one or more control circuits comprise state machine 312 (or a microcontroller or microprocessor) alone or in combination with controller 102.

In one embodiment, memory structure 326 comprises a monolithic three dimensional memory array of non-volatile memory cells in which multiple memory levels are formed above a single substrate, such as a wafer. The memory structure may comprise any type of non-volatile memory that is monolithically formed in one or more physical levels of arrays of memory cells having an active area disposed above a silicon (or other type of) substrate. In one example, the non-volatile memory cells of memory structure 326 comprise vertical NAND strings with charge-trapping material such as described, for example, in U.S. Pat. No. 9,721,662, incorporated herein by reference in its entirety. In another embodiment, memory structure 326 comprises a two dimensional memory array of non-volatile memory cells. In one example, the non-volatile memory cells are NAND flash memory cells utilizing floating gates such as described, for example, in U.S. Pat. No. 9,082,502, incorporated herein by reference in its entirety. Other types of memory cells (e.g., NOR-type flash memory) can also be used.

The exact type of memory array architecture or memory cell included in memory structure 326 is not limited to the examples above. Many different types of memory array architectures or memory cell technologies can be used to form memory structure 326. No particular non-volatile memory technology is required for purposes of the new claimed embodiments proposed herein. Other examples of suitable technologies for memory cells of the memory structure 326 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 326 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

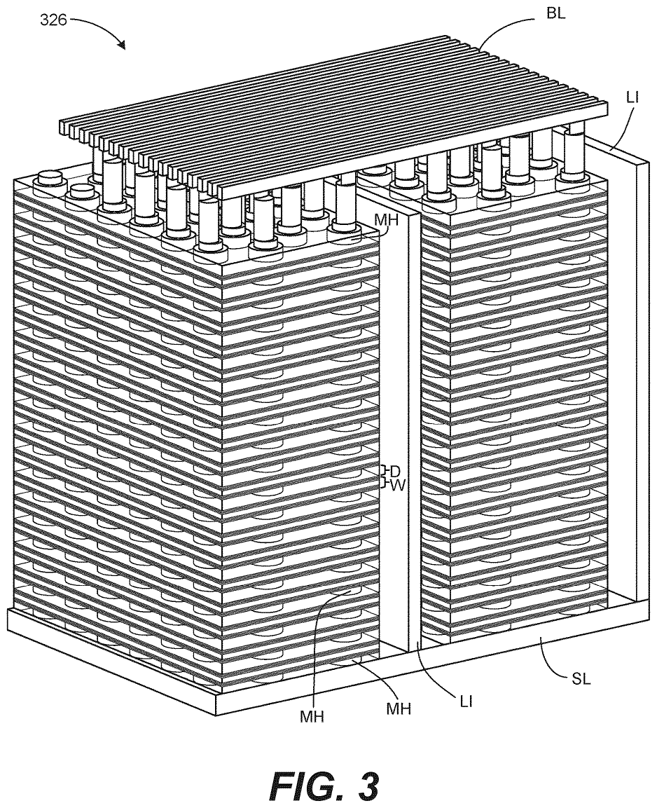

FIG. 3 is a perspective view of a portion of one example embodiment of a monolithic three dimensional memory array that can comprise memory structure 326, which includes a plurality memory cells. For example, FIG. 3 shows a portion of one block of memory. The structure depicted includes a set of bit lines BL positioned above a stack of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. One set of embodiments includes between 108-278 alternating dielectric layers and conductive layers, for example, 127 data word line layers, 8 select layers, 4 dummy word line layers and 139 dielectric layers.

Herein, different writing schemes are disclosed. One writing scheme is referred to as a “normal” writing scheme. A data word line layer (or data word line in a block) is defined herein as a layer in which either user data or system data may be stored in a normal writing scheme. A dummy word line layer (or dummy word line in a block) is defined herein as a layer that is not eligible to store either user data or system data in a normal writing scheme. Other writing schemes disclosed herein reduce read disturb, and are not defined as being a normal writing scheme. When using a scheme to reduce read disturb, dummy data may be stored in some of the word lines that are designated as data word lines for the normal writing scheme. It will be understood that a word line that is designated as a data word line when using the “normal” writing scheme will be referred to herein as a data word line when using a scheme that reduces read disturb, even if dummy data is stored in the word line. A data memory cell is defined herein as a memory cell connected to a data word line, and a dummy memory cell is defined herein as a memory cell that is connected to a dummy word line.

Further, the term “user/system” data, as used herein, refers to “user data” or to “system data.” The user data refers to data that a user of the memory system stores and reads from the memory structure 326. The system data refers to data that the memory system stores to and reads from the memory structure 326, and in general is not read by the user. However, even if the user is able to access such system data, that does not change its characterization as user/system data. The term user/system excludes “dummy data.” Dummy data refers to any data that is written to group of memory cells that does not contain useful information. Dummy data does not include user/system data. Note that the dummy data could include a pattern such as alternating “1s” and “0s”, or having all memory cells programmed to a minimum threshold voltage. However, such patterns are considered useful information for purposes of the definition of dummy data.

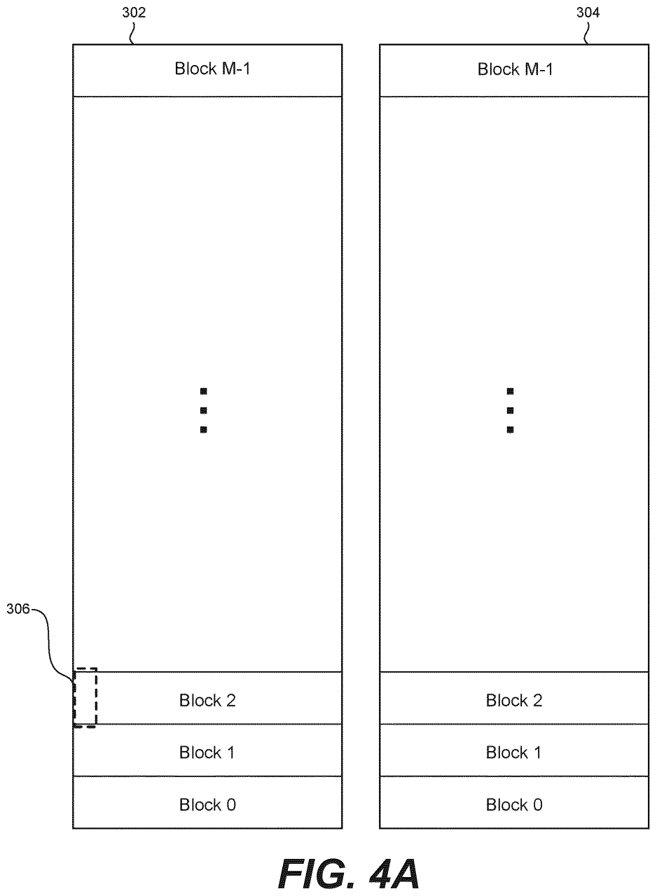

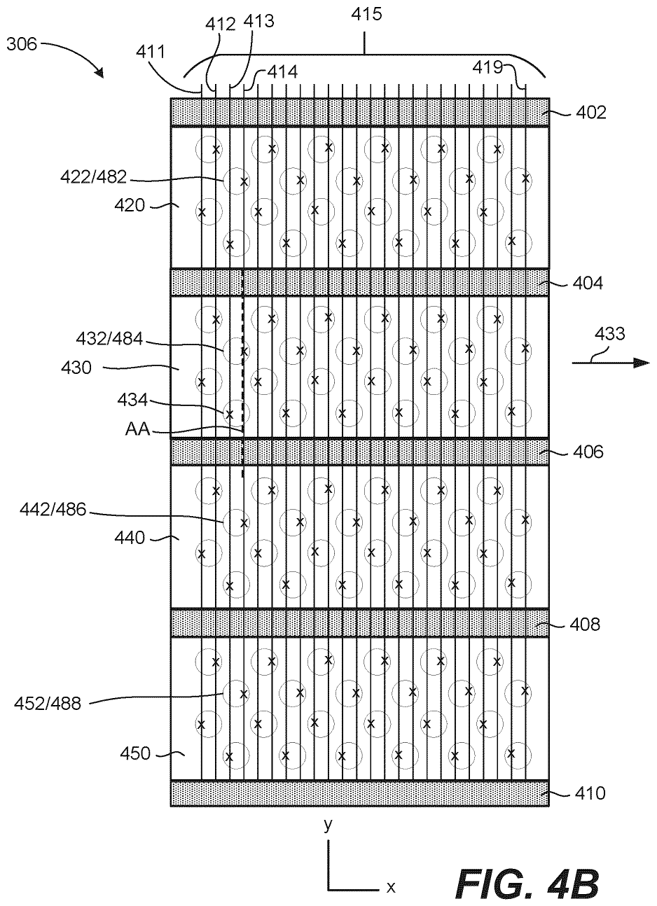

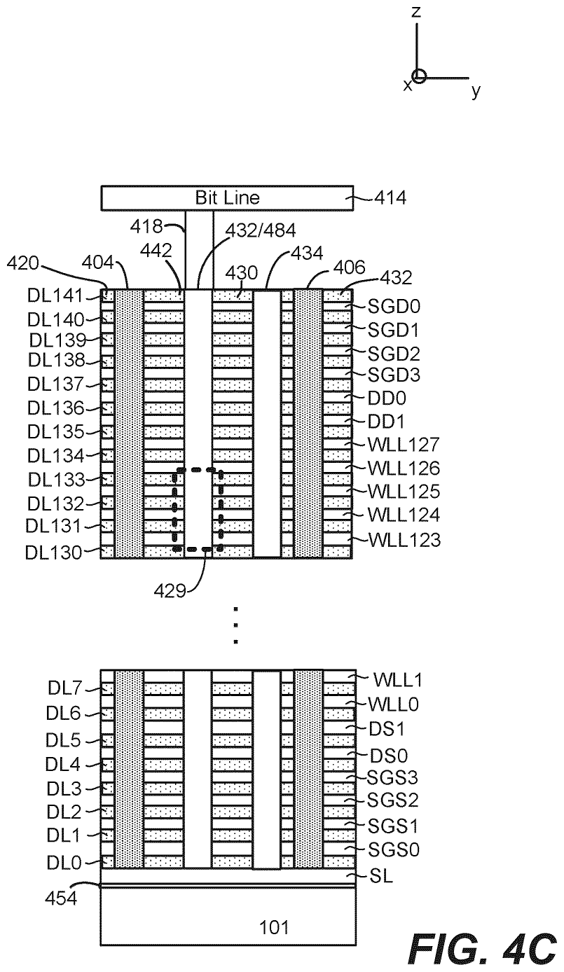

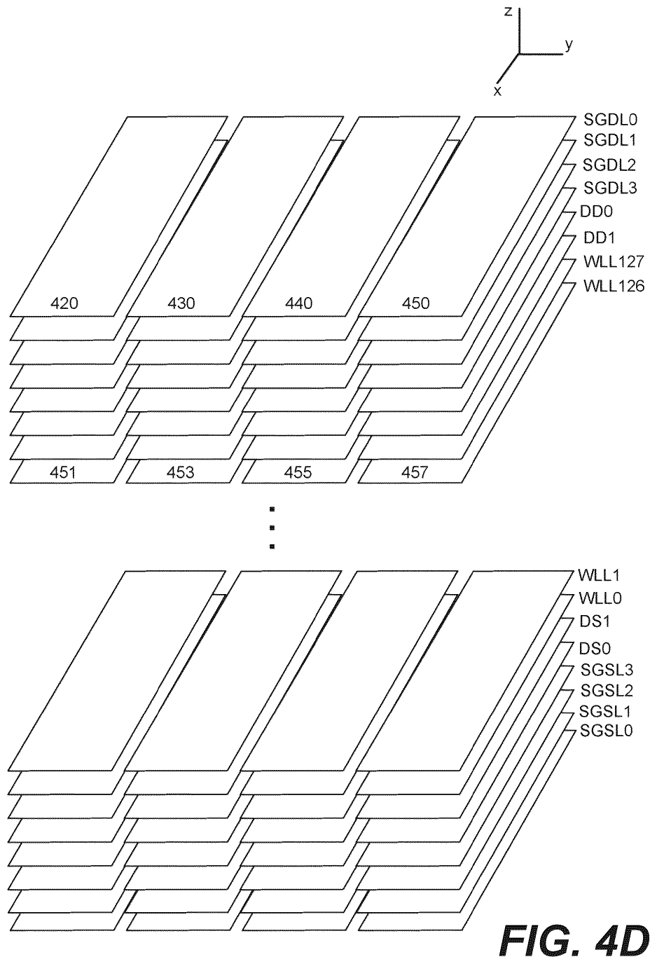

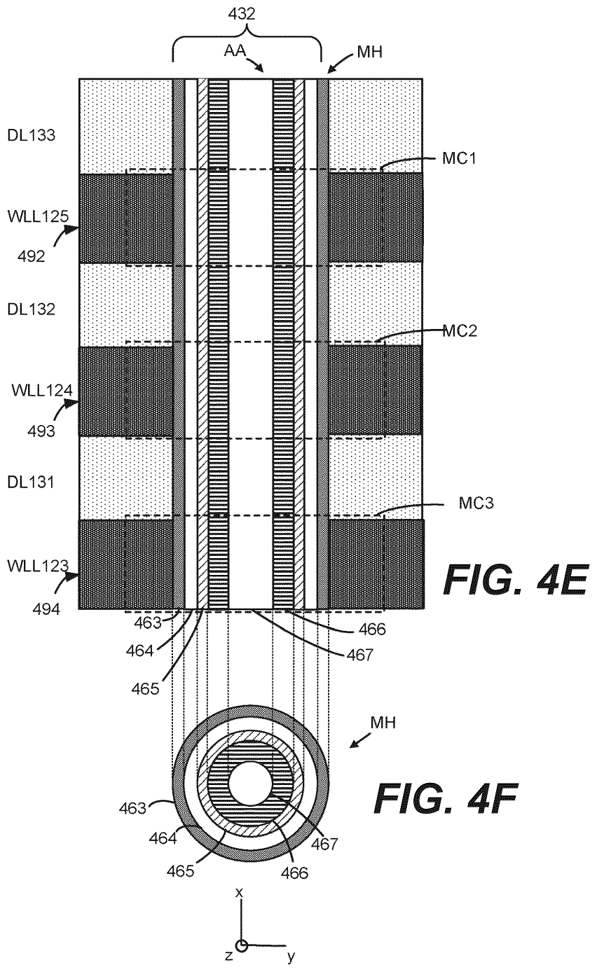

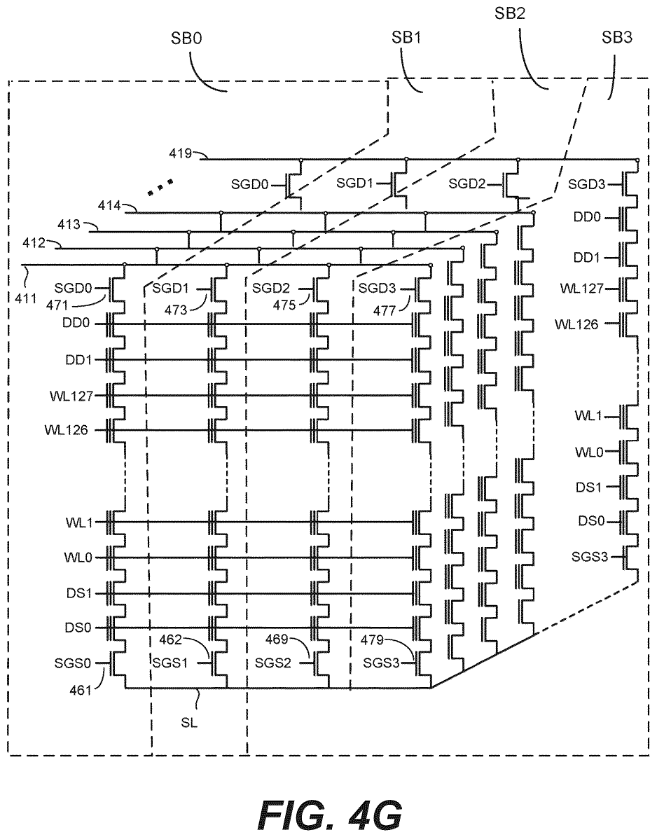

More or fewer than 108-278 layers can also be used. As will be explained below, the alternating dielectric layers and conductive layers are divided into four “fingers” by local interconnects LI. FIG. 3 shows two fingers and two local interconnects LI. Below and the alternating dielectric layers and word line layers is a source line layer SL. Memory holes are formed in the stack of alternating dielectric layers and conductive layers. For example, one of the memory holes is marked as MK Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping layer to create a vertical column of memory cells. Each memory cell can store one or more bits of data. More details of the three dimensional monolithic memory array that comprises memory structure 326 is provided below with respect to FIG. 4A-4G.

Due to limitations of the fabrication process, the memory holes (MH) might not be uniform in cross sectional shape from top to bottom of the memory structure 326. For example, the memory holes could, in general, have a smaller cross sectional area closer to the source line (SL). As will be explained below, the diameter of the memory holes may impact read disturb. Some embodiments factor in the diameter of the memory holes when determining a write scheme for read intensive data.

FIG. 4A is a block diagram explaining one example organization of memory structure 326, which is divided into two planes 302 and 304. Each plane is then divided into M blocks. In one example, each plane has about 2000 blocks. However, different numbers of blocks and planes can also be used. In on embodiment, a block of memory cells is a unit of erase. That is, all memory cells of a block are erased together. In other embodiments, memory cells can be grouped into blocks for other reasons, such as to organize the memory structure 326 to enable the signaling and selection circuits. In some embodiments, a block represents a groups of connected memory cells as the memory cells of a block share a common set of word lines.

FIGS. 4B-4G depict an example three dimensional (“3D”) NAND structure. FIG. 4B is a block diagram depicting a top view of a portion of one block from memory structure 326. The portion of the block depicted in FIG. 4B corresponds to portion 306 in block 2 of FIG. 4A. As can be seen from FIG. 4B, the block depicted in FIG. 4B extends in the direction of 433. In one embodiment, the memory array has sixty layers. Other embodiments have less than or more than sixty layers. However, FIG. 4B only shows the top layer.

FIG. 4B depicts a plurality of circles that represent the vertical columns. Each of the vertical columns include multiple select gates (also referred to as a select transistors) and multiple memory cells (also referred to as data memory cells). In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends in the direction of arrow 433, the block includes more vertical columns than depicted in FIG. 4B

FIG. 4B also depicts a set of bit lines 415, including bit lines 411, 412, 413, 414, . . . 419. FIG. 4B shows twenty four bit lines because only a portion of the block is depicted. It is contemplated that more than twenty four bit lines may be connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of one embodiment of a three dimensional memory structure 326 showing a cross-sectional view along line AA of FIG. 4B. This cross sectional view cuts through vertical columns 432 and 434 and region 430 (see FIG. 4B). The structure of FIG. 4C includes four drain side select layers SGD0, SGD1, SGD2 and SGD3 associated with the drain side select gates; four source side select layers SGS0, SGS1, SGS2 and SGS3 associated with the source side select gates; four dummy word line layers DD0, DD1, DS0 and DS1; and forty eight data word line layers WLL0-WLL127 for connecting to data memory cells. Other embodiments can implement more or less than four drain side select layers, more or less than four source side select layers, more or less than four dummy word line layers, and more or less than one hundred and twenty eight word line. Vertical columns 432 and 434 are depicted protruding through the drain side select layers, source side select layers, dummy word line layers and word line layers. In one embodiment, each vertical column comprises a NAND string. For example, vertical column 432 comprises NAND string 484. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to Bit Line 414 via connector 418. Local interconnects 404 and 406 are also depicted.

For ease of reference, drain side select layers SGD0, SGD1, SGD2 and SGD3; source side select layers SGS0, SGS1, SGS2 and SGS3; dummy word line layers DD0, DD1, DS0 and DS1; and word line layers WLL0-WLL127 collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL141. For example, dielectric layers DL131 is above word line layer WLL123 and below word line layer WLL124. In one embodiment, the dielectric layers are made from SiO₂. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layers WLL0-WLL127 connect to memory cells (also called data memory cells). Dummy word line layers DD0, DD1, DS0 and DS1 connect to dummy memory cells. A dummy memory cell does not store host data (data provided from the host, such as data from a user of the host), while a data memory cell is eligible to store host data. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

FIG. 4D depicts a logical representation of the conductive layers (SGD0, SGD1, SGD2, SGD3, SGS0, SGS1, SGS2, SGS3, DD0, DD1, DS0, DS1, and WLL0-WLL127) for the block that is partially depicted in FIG. 4C. As mentioned above with respect to FIG. 4B, in one embodiment local interconnects 402, 404, 406, 408 and 410 break up the conductive layers into four regions/fingers (or sub-blocks). For example, word line layer WLL126 is divided into regions 451, 453, 455 and 457. For word line layers (WLL0-WLL127), the regions are referred to as word line fingers; for example, word line layer WLL126 is divided into word line fingers 451, 453, 455 and 457. For example, region 451 is one word line finger on one word line layer. In one embodiment, the four word line fingers on a same level are connected together. In another embodiment, each word line finger operates as a separate word line.

Drain side select gate layer SGD0 (the top layer) is also divided into regions 420, 430, 440 and 450, also known as fingers or select line fingers. In one embodiment, the four select line fingers on a same level are connected together. In another embodiment, each select line finger operates as a separate word line.

FIG. 4E depicts a view of the region 429 of FIG. 4C. FIG. 4F depicts a cross section (in an x-y plane) of memory hole 432 of FIG. 4E. FIG. 4E depicts dielectric layers DLL131, DLL132, DLL133, as well as word line layers WLL123, WLL124, WLL125. In one embodiment, the vertical columns are round; however, in other embodiments other shapes can be used. Region 429 contains several memory cells MC1, MC2, MC3. The physical interaction of the word line layers with the vertical column forms the memory cells.

The memory hole 432 includes a number of memory cell films 463-467. For example, each column (e.g., the pillar which is formed by the materials within a memory hole) can include a blocking oxide/block high-k material 463, charge-trapping layer or film 464 such as SiN or other nitride, a tunneling layer 465, a polysilicon body or channel 466, and a dielectric core 467. A word line layer can include a conductive metal such as Tungsten as a control gate. For example, control gates 492, 493 and 494 are provided. In this example, all of the layers except the metal are provided in the memory hole. In other approaches, some of the memory film layers can be in the control gate layer. Thus, the memory hole 432 could contain fewer (or more) memory film layers than are shown in FIGS. 4E and 4F. Also note that some of the depicted layers may be formed from one or more layers. Additional pillars are similarly formed in the different memory holes. A pillar can form a columnar active area (AA) of a NAND string.

When a memory cell transistor is programmed, electrons are stored in a portion of the charge-trapping layer 464 which is associated with the memory cell transistor. These electrons are drawn into the charge-trapping layer from the channel 466, and through the tunneling layer 465. The Vt of a memory cell transistor is increased in proportion to the amount of stored charge. During an erase operation, the electrons return to the channel. Non-data transistors (e.g., select transistors, dummy memory cell transistors) may also include the charge trapping layer 464. Thus, the threshold voltage of at least some non-data transistors may also be adjusted by storing or removing electrons from the charge trapping layer 464. It is not required that all non-data transistors have an adjustable Vt. For example, the charge trapping layer 464 is not required to be present in every select transistor.

In some embodiments, the memory hole is formed by drilling (or etching) holes into a stack of alternating layers (e.g., alternating layers of a conductive material and a sacrificial material). The term “memory hole” may be used to refer to both the empty region that exists after drilling (or etching) holes into the stack or to the region after it has been filled with the memory cell film. The memory cell films may be deposited on the sidewall of the memory hole. For example, first the blocking layer 463 may be deposited on the memory hole sidewall using atomic layer deposition, or another deposition technique. Then, then charge trapping layer 464 may be deposited over the blocking layer 463. Next, the tunneling layer 465 may be deposited over the charge trapping layer 464. In some cases, the tunneling layer 465 can comprise multiple layers such as in an oxide-nitride-oxide configuration. Then, the body 466 may be deposited over the tunneling layer 465. Note that it is the body 466 that connects to the bit line and the source line. Then, the dielectric core 467 may be formed within the body 466. Other techniques may be used to form the memory cell film. The technology described herein is not limited to any particular material or structure.

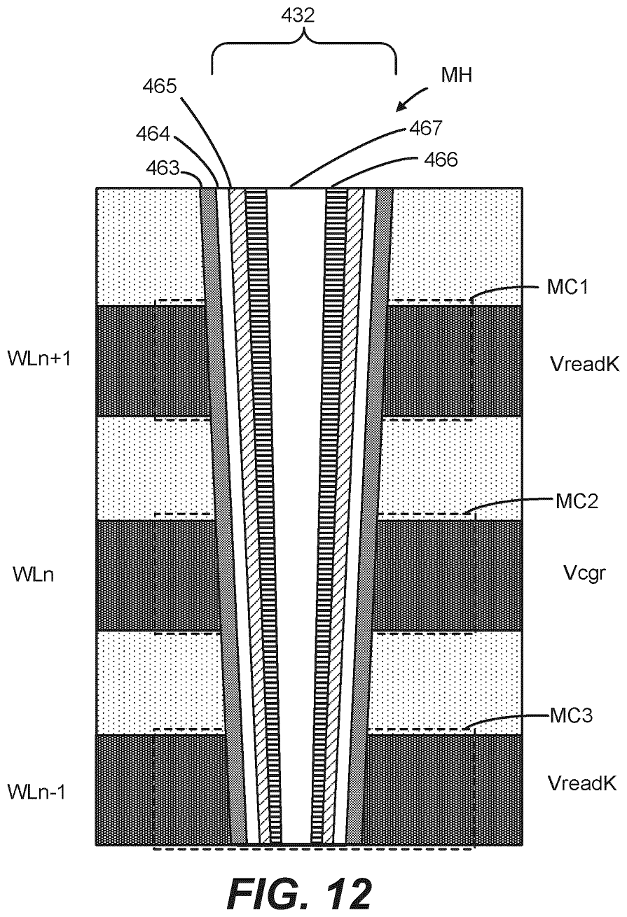

Note that although the diameter of the memory hole 432 is depicted as being relatively uniform from DL133 to WLL123, there may be some tapering of the memory hole (which may also be stated as tapering of the column). Briefly, FIG. 12 depicts an example in which the memory hole 432 tapers. In other words, the column has a diameter that varies depending on location of the non-volatile memory cells along the column. As will be discussed below, the tapering of the memory hole may result in read disturb impacting some word line layers more severely than others. For example, memory cells formed in memory holes having a smaller diameter may be more susceptible to read disturb. In some embodiments, a write scheme is selected for high read intensive blocks based on the diameter of the memory holes.

FIG. 4G is a schematic diagram of a portion of the memory depicted in in FIGS. 3-4F. FIG. 4G shows physical word lines WLL0-WLL127 running across the entire block. The structure of FIG. 4G corresponds to portion 306 in Block 2 of FIGS. 4A-F, including bit lines 411, 412, 413, 414, . . . 419. Within the block, each bit line is connected to four NAND strings. Drain side selection lines SGD0, SGD1, SGD2 and SGD3 are used to determine which of the four NAND strings connect to the associated bit line(s). The transistors 471, 473, 475, 477 connected to the drain side selection lines SGD0, SGD1, SGD2 and SGD3 are drain side select gates. Source side selection lines SGS0, SGS1, SGS2 and SGS3 are used to determine which of the four NAND strings connect to the common source line. The transistors 461, 462, 469, 479 connected to the source side selection lines SGS0, SGS1, SGS2 and SGS3 are source side select gates. The block can also be thought of as divided into four sub-blocks SB0, SB1, SB2 and SB3. Sub-block SB0 corresponds to those vertical NAND strings controlled by SGD0 and SGS0, sub-block SB1 corresponds to those vertical NAND strings controlled by SGD1 and SGS1, sub-block SB2 corresponds to those vertical NAND strings controlled by SGD2 and SGS2, and sub-block SB3 corresponds to those vertical NAND strings controlled by SGD3 and SGS3.

Although the example memory system of FIGS. 3-4G is a three dimensional memory structure that includes vertical NAND strings with charge-trapping material, other (2D and 3D) memory structures can also be used with the technology described herein.

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate. FIG. 5 illustrates example threshold voltage distributions for the memory array when each memory cell stores three bits of data. Other embodiments, however, may use other data capacities per memory cell (e.g., such as one, two, four, or five bits of data per memory cell). Storing more than one bit of data per memory cell is referred to a MLC. Storing one bit of data per memory cell is referred to a SLC. FIG. 5 shows eight threshold voltage distributions, corresponding to eight data states. The first threshold voltage distribution (data state) S0 represents memory cells that are erased. The other seven threshold voltage distributions (data states) S1-S17 represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected.

FIG. 5 shows seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (i.e., S0, S1, S2, S3, . . . ) a memory cell is in.

FIG. 5 also shows seven verify reference voltages, Vv1, Vv2, Vv3, Vv4, Vv5, Vv6 and Vv7. When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv5. When programming memory cells to data state S6, the system will test whether those memory cells have a threshold voltage greater than or equal to Vv6. When programming memory cells to data state S7, the system will test whether those memory cells have a threshold voltage greater than or equal to Vv7. FIG. 5 also shows Vev, which is a voltage level to test whether a memory cell has been properly erased.

In one embodiment, known as full sequence programming, memory cells can be programmed from the erased data state S0 directly to any of the programmed data states S1-S7. For example, a population of memory cells to be programmed may first be erased so that all memory cells in the population are in erased data state S0. Then, a programming process is used to program memory cells directly into data states S1, S2, S3, S4, S5, S6, and/or S7. For example, while some memory cells are being programmed from data state S0 to data state S1, other memory cells are being programmed from data state S0 to data state S2 and/or from data state S0 to data state S3, and so on. The arrows of FIG. 5 represent the full sequence programming. The technology described herein can also be used with other types of programming in addition to full sequence programming (including, but not limited to, multiple stage/phase programming). In some embodiments, data states S1-S7 can overlap, with controller 102 relying on error correction to identify the correct data being stored.

FIG. 6 is a table describing one example of an assignment of data values to data states. In the table of FIG. 6, S0=111, S1=110, S2=100, S3=000, S4=010, S5=011, S6=001 and S7=101. Other encodings of data can also be used. No particular data encoding is required by the technology disclosed herein. In one embodiment, when a block is subjected to an erase operation, all memory cells are moved to data state S0, the erased state. In the embodiment of FIG. 6, all bits stored in a memory cell are 1 when the memory cells are erased (e.g., in data state S0).

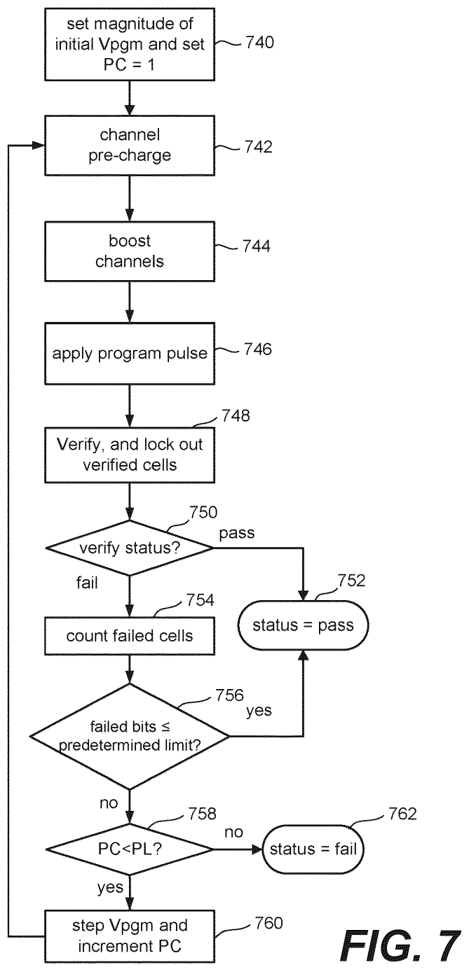

FIG. 7 is a flow chart describing one embodiment of a process for programming. In some embodiments, data is programmed (written) in pages and read in pages. In one embodiment, a page includes all data stored in memory cells connected to a common word line. In one embodiment, a page includes one bit of data stored in each memory cell connected to a common word line. In one embodiment, a page includes all data stored in a subset of memory cells connected to a common word line. In one embodiment, a page includes all (or one bit of) data stored in memory cells of the same sub-block connected to a common word line. In one example embodiment, the process of FIG. 7 is performed on memory die 300 using the control circuit discussed above. For example, the process of FIG. 7 can be performed at the direction of state machine 312.

Typically, the program voltage applied to the control gates (via a selected word line) during a program operation is applied as a series of program pulses. Between at least some of the programming pulses are a set of verify pulses to perform verification. In many implementations, the magnitude of the program pulses is increased with each successive pulse by a predetermined step size. In step 740 of FIG. 7, the programming voltage (Vpgm) is initialized to the starting magnitude (e.g., \tilde{ }12-16V or another suitable level) and a program counter PC maintained by state machine 312 is initialized at 1.

In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. For example, when data is written to a set of memory cells, some of the memory cells will need to store data associated with state S0 so they will not be programmed. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 742 the memory system will pre-charge channels of NAND strings that include memory cells connected to the selected word line that are to be inhibited from programming. In some embodiments, the channel is pre-charged from the drain end of the NAND string. By “drain end” it is meant the end of the NAND string connected to the bit line. In some embodiments, the channel is pre-charged from the source end. By “source end” it is meant the end of the NAND string connected to the source line. In some embodiments, the channel is pre-charged from both the drain end and the source end.

In step 744, NAND strings that include memory cells connected to the selected word line that are to be inhibited from programming have their channels boosted to inhibit programming. Such NAND strings are referred to herein as “unselected NAND strings.” In one embodiment, the unselected word lines receive one or more boosting voltages (e.g., \tilde{ }7-11 volts) to perform boosting schemes. A program inhibit voltage is applied to the bit lines coupled the unselected NAND string. This allows the boosting voltages to boost the potential of the NAND channel.

In step 746, a program pulse of the program signal Vpgm is applied to the selected word line (the word line selected for programming). If a memory cell on a NAND string should be programmed, then the corresponding bit line is biased at a program enable voltage, in one embodiment. Herein, such a NAND string is referred to as a “selected NAND string.” In step 746, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 748, memory cells that have reached their target states are locked out from further programming. Step 748 may include performing verifying at one or more verify reference levels. In one embodiment, the verification process is performed by testing whether the threshold voltages of the memory cells selected for programming have reached the appropriate verify reference voltage. The verify reference voltage is at a lower tail of the target state, in one embodiment. As used herein “lower tail” refers to a portion of distribution between its lowest threshold voltage level and the threshold voltage level at the apex of the distribution. Similarly, as used herein “upper tail” refers to a portion of distribution between its highest threshold voltage level and the threshold voltage level at the apex of the distribution.

In step 748, a memory cell may be locked out after the memory cell has been verified (by a test of the Vt) that the memory cell has reached its target state.

If, in step 750, it is determined that all of the memory cells have reached their target threshold voltages (pass), the programming process is complete and successful because all selected memory cells were programmed and verified to their target states. A status of “PASS” is reported in step 752. Otherwise if, in 750, it is determined that not all of the memory cells have reached their target threshold voltages (fail), then the programming process continues to step 754.

In step 754, the memory system counts the number of memory cells that have not yet reached their respective target threshold voltage distribution. That is, the system counts the number of memory cells that have, so far, failed to reach their target state. This counting can be done by the state machine, the controller 102, or other logic. In one implementation, each of the sense blocks will store the status (pass/fail) of their respective cells. In one embodiment, there is one total count, which reflects the total number of memory cells currently being programmed that have failed the last verify step. In another embodiment, separate counts are kept for each data state.

In step 756, it is determined whether the count from step 754 is less than or equal to a predetermined limit. In one embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 752. In this situation, enough memory cells programmed correctly such that the few remaining memory cells that have not been completely programmed can be corrected using ECC during the read process. In some embodiments, the predetermined limit used in step 756 is below the number of bits that can be corrected by error correction codes (ECC) during a read process to allow for future/additional errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, than the programming process continues at step 758 and the program counter PC is checked against the program limit value (PL). Examples of program limit values include 7, 12, 16, 19 and 30; however, other values can be used. If the program counter PC is not less than the program limit value PL, then the program process is considered to have failed and a status of FAIL is reported in step 762. If the program counter PC is less than the program limit value PL, then the process continues at step 760 during which time the Program Counter PC is incremented by 1 and the program voltage Vpgm is stepped up to the next magnitude. For example, the next pulse will have a magnitude greater than the previous pulse by a step size (e.g., a step size of 0.1-1.0 volts). After step 760, the process loops back to step 742 and another program pulse is applied to the selected word line so that another iteration (steps 742-660) of the programming process of FIG. 7 is performed.

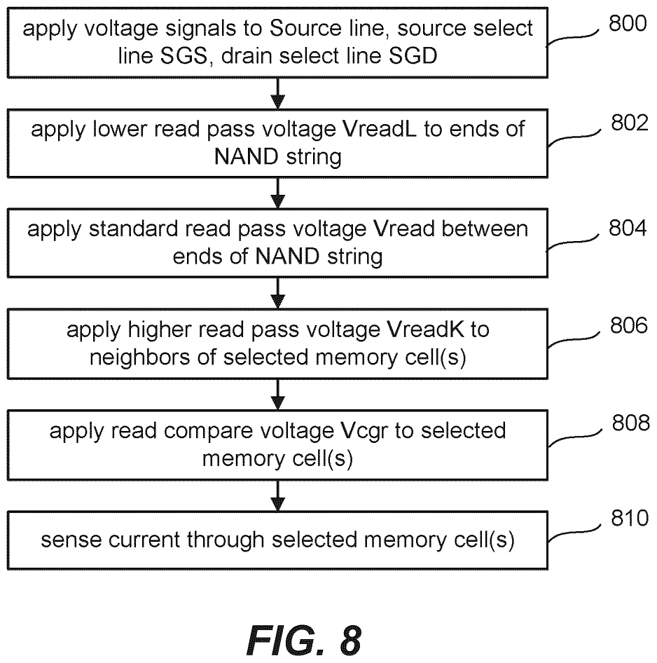

FIG. 8 is a flowchart of one embodiment of a process of reading non-volatile memory cells. Step 800 of FIG. 8 includes applying voltage signals to the source line, source select line SGS and drain select line SGD. In step 802, a lower read pass voltage, VreadL, is applied to memory cells at the ends of the NAND string. In step 804, the standard read pass voltage, Vread, is applied to the middle memory cells, which are those memory cells between the ends of the NAND string that are not selected for reading. In step 806, a higher read pass voltage, VreadK, is applied to those memory cells of the NAND string that are neighbors to the selected memory cell. In step 808, the read compare voltage, Vcgr, is applied to the selected memory cell. In step 810, the system will sense the current through the selected memory cell in response to the voltages applied in steps 800-808.

In many embodiments, the system will read multiple memory cells at the same time. Therefore, the process of FIG. 8 will be performed concurrently on multiple NAND strings of the same block such that multiple memory cells will be read concurrently.

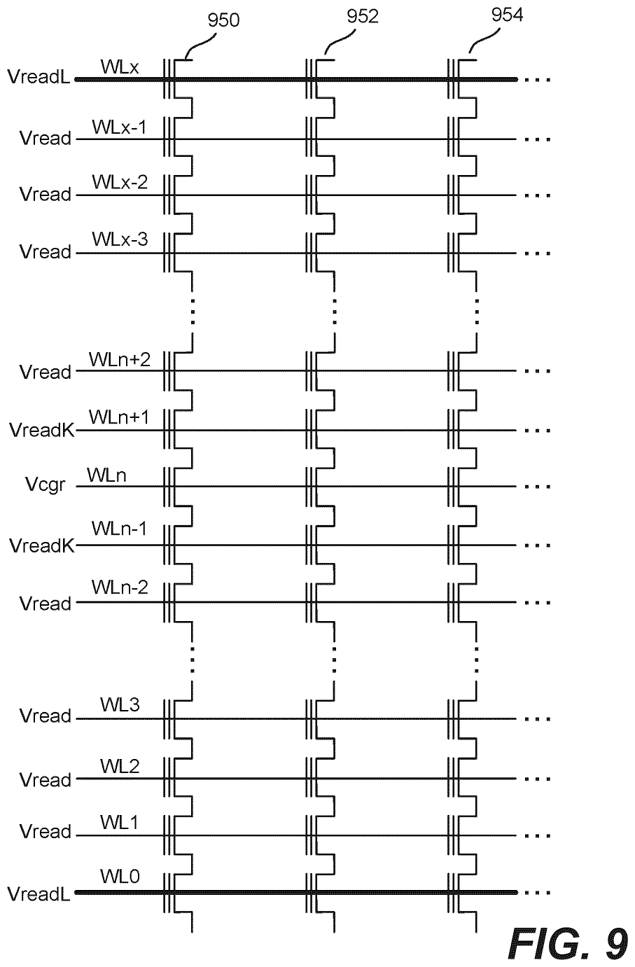

FIG. 9 shows three NAND strings 950, 952 and 954 of a block of memory cells implementing the process of FIG. 8. In the example embodiment of FIG. 9, a NAND string will include x+1 memory cells. Therefore, the block of NAND strings will include x+1 word lines (WL0-WLx). In the depicted example, word line WLn is selected for reading; therefore, all the memory cells connected to WLn will be read. As per step 808 of FIG. 8, FIG. 9 shows WLn receiving Vcgr, the read compare voltage. As per step 806 of FIG. 8, FIG. 9 shows neighboring word lines WLn−1 and WLn+1 receiving the higher read pass voltage, VreadK. As per step 804 FIG. 8, FIG. 9 shows the word lines (WL1, WL2 . . . WLN−2, WLN+2, . . . WLx−3, WLx−2, WLx−1) that are not connected to end memory cells receiving the standard read pass voltage, Vread. As per step 802 of FIG. 8, FIG. 9 shows the end word lines (in the example, the word lines at the extreme end of the NAND string), WL0 and WLx, receiving the lower read pass voltage VreadL. In this embodiment, the various voltages Vread, VreadL and VreadK are provided to the control gates of the respective memory cells by applying the voltages to the word lines, which are connected to the control gates of memory cells. As seen from FIG. 9, each word line is connected to the control gate of multiple memory cells so that the read and programming operations are performed in parallel.

If any word line in a block is read often, the data in the neighboring word line may get corrupted due to Read Disturb (RD). When a word line WLn is read, a bypass voltage VreadK is applied on the neighboring word lines WLn+1 and WLn−1, in some embodiments. VreadK is Vread+dvreadk (offset). Other unselected WLs have Vread (or VreadL on source side and drain side). Since VreadK>Vread, a weak programming may happen on the neighboring word lines (WLn−1 and WLn+1). Therefore, the optimum read levels may shift towards from default levels, especially for Er-A (data states S0-S1) valley point.

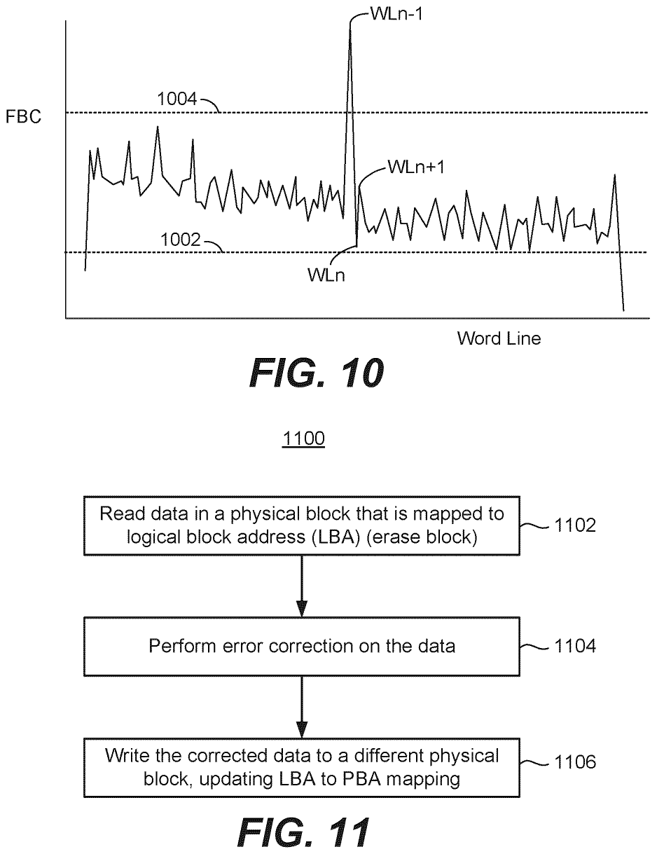

FIG. 10 shows an example plot of fail bit count (FBC) versus word line. The plot shows the effect of read disturb on each of the word lines after many reads of a selected word line (WLn). In particular, the plot is used to demonstrate an impact of read disturb on word lines that neighbor the selected word line. The two neighboring word lines are word line WLn−1 (closer to the source line) and WLn+1 (closer to the bit line). The FBC of the neighboring word lines are high relative to the selected word line (WLn).

The memory controller 102 has an ability to correct a certain number of “failed bits” using its error correction engine. Line 1002 represents a number of bits that can be corrected using a first error correction algorithm. Line 1004 represents a number of bits that can be corrected using a second error correction algorithm. Although the second error correction algorithm can correct more failed bits, the second error correction algorithm typically takes more time to converge. When the read disturb is too high, the first error correction algorithm is not able to correct the data. In most cases, the second error correction algorithm can correct the data. However, even the second error correction algorithm may be unable to correct the data for WLn−1 in this example. Hence, read scrub may need to be performed at a much higher frequency in order to be able to successfully decode the data in WLn−1.

Read scrub may be used to address the read disturb issue. Read scrub is a conservative approach in which the data on the verge of going beyond the system's error correction capability due to read disturb is identified. The identified data is moved to a fresh block, in some embodiments. FIG. 11 is a flowchart of one embodiment of a read scrub. This process 1100 is invoked in response to identifying a physical block of data that should be scrubbed. One technique for triggering a read scrub is based on a read count with respect to the physical block. Another technique for triggering read scrub is based on a number of failed bits when reading data in the block. However, techniques may be used to trigger a read scrub.

In step 1102, data is read from the physical block. The physical block is associated with a logical block address (LBA), as discussed above. The memory controller 102 contains an LBA to PBA (physical block address) mapping, in some embodiments. After reading the data, the physical block is erased, although the erase may be put off until a later time. The data is transferred to the memory controller 102. Step 1104 includes the memory controller 102 performing error correction on the data. Thus, the memory controller 102 corrects any failed bits.

Step 1106 includes writing the data to a different physical block. Step 1106 also includes updating the LBA to PBA mapping. In other words, the LBA remains the same. Although the data is typically written to a different physical block in step 1106, another alternative is to erase the physical block from step 1102 and re-write the data into the same physical block.

Although read scrub is very useful to protect the integrity of the data, performing read scrub too often may reduce the useful lifetime of the memory device. As can be seen in the flow of FIG. 11, the read scrub process results in an erase of a block and a write of a block. If read scrub us triggered too often, the erasing and programming will negatively impact the write endurance and system performance. High read intensive blocks could potentially undergo a read scrub process a high number of times. Therefore, high read intensive blocks could potentially reduce the useful lifetime of the memory device. However, embodiments are able to increase the useful lifetime of the memory device by reducing the frequency with which high read intensive blocks are scrubbed.

The NAND strings may be formed in memory holes (see FIGS. 3, 4B, 4C, 4E). Due to limitations of the fabrication process, the memory holes might not be uniform in cross sectional shape from top to bottom of the stack. For example, the memory hole may taper. That is, the memory hole may become progressively smaller at one end. FIG. 12 depicts an example of a memory hole that tapers. The amount of taper is exaggerated to help illustrate the effect of tapering. FIG. 12 depicts just a few word lines, showing conditions under which a read reference voltage (Vcgr) is applied to a selected word line (WLn) and VreadK is applied to two neighboring word lines.

In 3D NAND, different WLs may be impacted by read disturb differently because of the change in the diameter along the Memory Hole (MH). When the MH diameter is smaller, the E-field under VreadK stress may be strong (relative to larger MH diameter) resulting in more severe read disturb. Thus, read disturb could be more severe for memory cells with a smaller MH diameter.

The memory hole diameter depends on the location of the word line, in some embodiments. In one embodiment of FIG. 4C, the memory hole diameter is largest at WLL 127 and smallest at WLL0. In some embodiments, the stack is divided into two or more tiers. For example, WLL0-WLL63 may be in a lower tier and WLL64-WLL127 may be in an upper tier. The memory hole diameter may taper in each tier, such that for the upper tier the memory hole diameter is largest at WLL127 and smallest at WLL64, and for the lower tier the memory hole diameter is largest at WLL63 and smallest at WLL0. However, the memory hole diameter at the top of the lower tier (e.g., WLL63) may be larger than the memory hole diameter at the bottom of the upper tier (e.g., WLL64). Thus, read disturb depends on the location of the selected word line, in some embodiments.

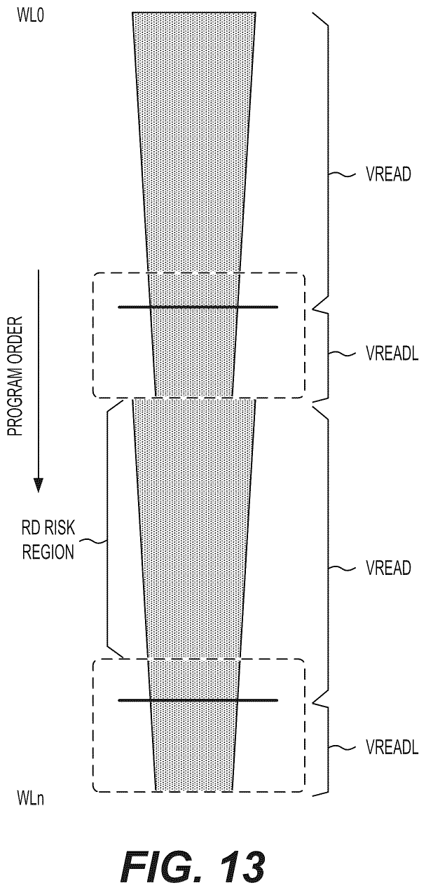

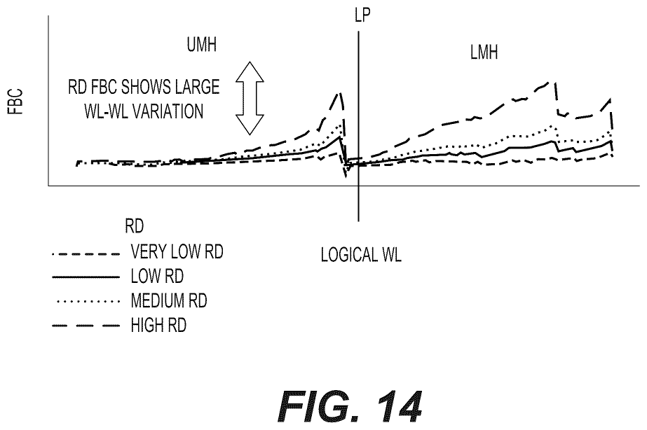

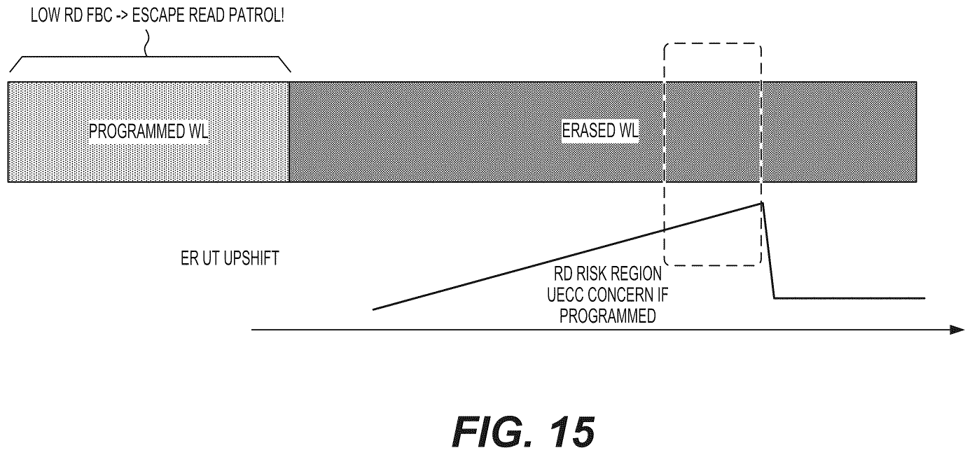

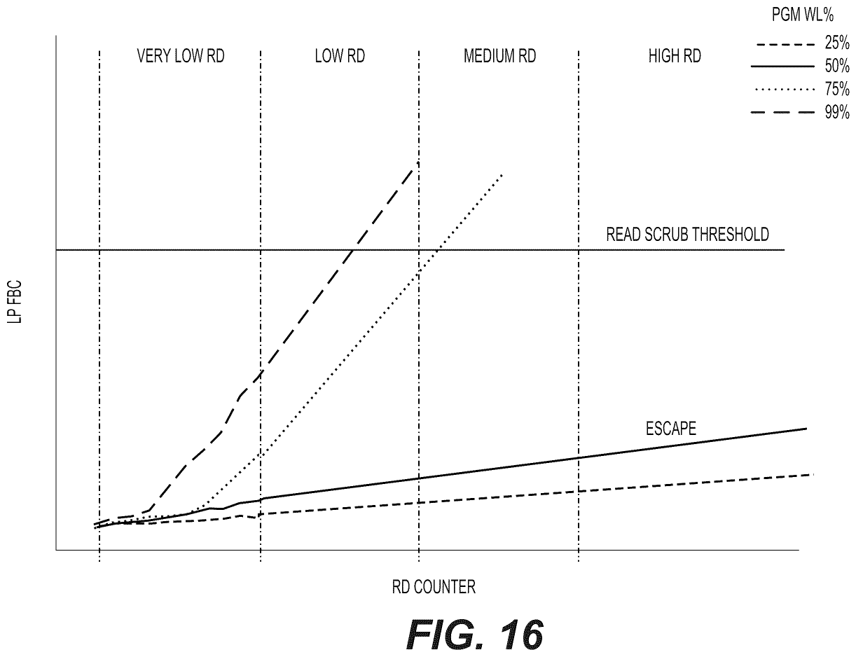

As discussed, various factors may cause some blocks to not be flagged by the read patrol or read scrub after heavy read disturb (RD). More specifically, the memory cells connected to different word lines respond to RD stress differently due to intrinsic process variation (e.g., memory hole diameter and circularity variations, etc.) and bias condition. FIG. 13 depicts another example of a memory hole formed of two tiers that each taper and illustrates read disturb risk regions. Every memory apparatus generation shows similar trend, the memory cells connected top word lines located at or near the bottom of a stack of the word lines of each tier are more susceptible to RD stress. FIG. 14 show a plot of the failure bit count versus logical word line for various read disturb scenarios. FIG. 15 shows a block with some erased word lines and fewer programmed word lines along with a plot showing a corresponding erase upper tail (UT) upshift with a read disturb risk region. FIG. 16 is a plot of failure bit count versus read disturb count. As shown, high openness blocks (i.e., those with more memory cells in the erased state than programmed) escape the read patrol. Specifically, due to large word line to word line variation in RD failure bit count (FBC), open blocks (i.e., those with the memory cells in the erased state, rather than being programmed) with higher openness (e.g., programmed word lines <40%) are not flagged by read patrol after heavy RD, as lower logical word lines have better RD resistance (e.g., RD risk regions in FIGS. 13 and 15). These open blocks will later be closed as normal, resulting in high FBC or even uncorrectable error correction code (UECC) in multiple word lines with worst RD resistance, due to lack of margin or overlap between the threshold voltage distributions of the erased state and the A or S1 data state (Er2A margin) by open block RD history. Thus, it would be desirable to detect the open block RD history early before the data is written on worst RD word lines.

Consequently, described herein is a memory apparatus (e.g., memory system 100 of FIG. 1A, memory die 300 of FIG. 2) including memory cells (e.g., memory cells MC1, MC2, MC3 of FIG. 4E) each connected to one of a plurality of word lines (e.g., word line layers WLL0-WL127 in FIG. 4C) and disposed in memory holes (e.g., memory hole MH of FIG. 3, vertical columns 422, 432, 442, and 452 of FIGS. 4B-4C and 4E) each connected to one of a plurality of bit lines (e.g., bit line BL of FIG. 3, bit line 414 of FIG. 4C). The memory cells are configured to retain a threshold voltage corresponding to a plurality of data states (e.g., threshold voltage distributions shown in FIG. 5). The memory holes are grouped into a plurality of blocks (e.g., block 0-block M-1 of FIG. 4A). The memory apparatus also includes a control circuit or means (e.g., one or any combination of controller 102 of FIG. 1A, Front End Processor Circuit (FEP) 110 and Back End Processor Circuits (BEP) 112 of FIGS. 1B and 1C, control circuitry 310, read/write circuits 328 of FIG. 2 and so forth). The control means is configured to read and count a data mismatch count (DMC) of the memory cells connected to a predetermined one of the plurality of word lines WORST RD WL of one of the plurality of blocks having the threshold voltage greater than a predetermined read threshold voltage in response to an open block read disturb detection operation (OB RDLA) being triggered prior to data being programmed to the memory cells of the one of the plurality of blocks. The control means is also configured to stop programming the memory cells of the one of the plurality of blocks and relocate the data to another one of the plurality of blocks in response to the data mismatch count being greater than a predetermined mismatch threshold.

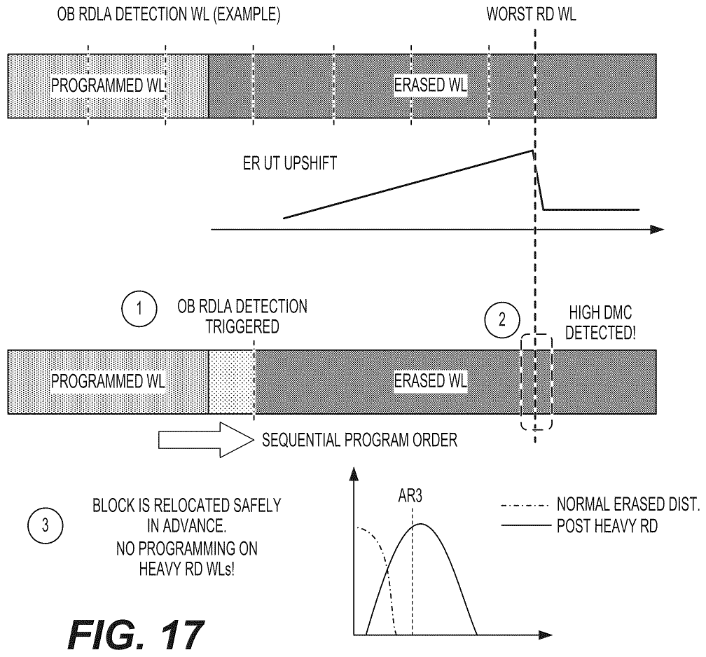

FIG. 17 shows a first view of a block with some erased word lines and fewer programmed word lines along with a plot showing a corresponding erase upper tail (UT) upshift in an upper portion and a second view of the block during a program operation in which the open block read disturb detection operation is triggered (indicated with the circled number 1), high data mismatch count on the predetermined one of the plurality of word lines WORST RD WL (indicated with the circled number 2), and the data of the block relocated (indicated with the circled number 3) along with a plot showing the threshold voltage distribution of the erased state and the A or S1 data state after heavy read disturb in a lower portion. According to an aspect, the predetermined one of the plurality of word lines WORST RD WL is known to exhibit worse read disturb than others of the plurality of word lines in other similar memory apparatuses. According to another aspect and as shown in FIG. 17, the predetermined one of the plurality of word lines WORST RD WL is connected to ones of the memory cells that are erased.

According to yet another aspect, the plurality of word lines includes a plurality of predetermined open block read disturb trigger word lines (e.g., dashed vertical lines of top portion of FIG. 17). The plurality of predetermined open block read disturb trigger word lines can be predetermined ahead of time and stored in the memory apparatus as parameter inputs. For example, according to an aspect, the plurality of predetermined open block read disturb trigger word lines can include approximately 5-10 pages or word lines to minimize performance impact. Thus, the control means is further configured to determine whether the memory cells being programmed are connected to one of the plurality of predetermined open block read disturb trigger word lines. The control means is also configured to determine the open block read disturb detection operation is triggered in response to determining the memory cells being programmed are connected to one of the plurality of predetermined open block read disturb trigger word lines.

As mentioned above, the plurality of word lines (e.g., W in FIG. 3, word line layers WLL0-WL127 in FIG. 4C) and a plurality of dielectric layers (e.g., D in FIG. 3, dielectric layers DL0-DL141 of FIG. 4C) extend horizontally and overlay one another in an alternating fashion in a stack (e.g., memory structure 326 of FIG. 3). The memory holes (e.g., memory hole MH of FIG. 3, vertical columns 422, 432, 442, and 452 of FIGS. 4B-4C and 4E) extend vertically through the stack. The memory cells are connected in series between at least one drain-side select gate transistor (e.g., SGD0-SGD3 in FIG. 4C) on a drain-side of each of the memory holes and at least one source-side select gate transistor (e.g., SGS0-SGS3 in FIG. 4C) on a source-side of each of the memory holes. The at least one drain-side select gate transistor of each of the memory holes is coupled to one of a plurality of bit lines (e.g., bit line 414 of FIG. 4C) and the source-side select gate transistor of each of the memory holes is connected to a source line (e.g., source line SL of FIG. 4C). According to an aspect, the plurality of predetermined open block read disturb trigger word lines (e.g., dashed vertical lines of top portion of FIG. 17) are evenly spaced vertically. The predetermined one of the plurality of word lines WORST RD WL is vertically closer to a bottom of the stack than a top of the stack (see e.g., right hand side of blocks of FIG. 17).

According to additional aspects of the disclosure, each of the memory cells is configured to store three bits and threshold voltage corresponds to one of a plurality of data states. The plurality of data states includes, in order of the threshold voltage increasing in magnitude, an erased data state (e.g., S0 data state of FIG. 5), a first data state (e.g., S1 data state of FIG. 5), a second data state (e.g., S2 data state of FIG. 5), a third data state (e.g., S3 data state of FIG. 5), a fourth data state (e.g., S4 data state of FIG. 5), a fifth data state (e.g., S5 data state of FIG. 5), a sixth data state (e.g., S6 data state of FIG. 5), and a seventh data state (e.g., S7 data state of FIG. 5). The predetermined read threshold voltage is equal to a read compare voltage associated with the first data state plus a predetermined delta (i.e., AR3+Δ). Nevertheless, it should be appreciated that it is contemplated that the memory cells store other amounts of bits (e.g., four level QLC cells). So, the control means, as part of the open block read disturb detection operation, is further configured to read and count the data mismatch count of the memory cells connected to the predetermined one of the plurality of word lines WORST RD WL of one of the plurality of blocks having the threshold voltage greater than the read compare voltage associated with the first data state plus the predetermined delta in response to the open block read disturb detection operation being triggered prior to data being programmed to the memory cells of the one of the plurality of blocks. It should be understood that the read compare voltage may alternatively be associated with another one of the plurality of data states and various values of the predetermined delta may be utilized. The control means is additionally configured to determine whether the data mismatch count is greater than the predetermined mismatch threshold. In addition, the control means is configured to stop programming the memory cells of the one of the plurality of blocks and relocate the data to another one of the plurality of blocks in response to the data mismatch count being greater than the predetermined mismatch threshold. The control means is also configured to continue programming the memory cells of the one of the plurality of blocks in response to the data mismatch count not being greater than the predetermined mismatch threshold.

The open block read disturb detection operation is also compatible with an enhanced post-write read (EPWR) error management operation (i.e., failure detection). Such functionality is disclosed in U.S. Pat. No. 8,873,288, incorporated herein by reference. Thus, according to further aspects, the plurality of word lines includes a plurality of predetermined post-write read error trigger word lines. Similar to the plurality of predetermined open block read disturb trigger word lines, these can be determined ahead of time and a list of them stored in the memory apparatus. Therefore, the control means is further configured to begin programming the memory cells of a particular one of the plurality of word lines. In addition, the control means is configured to determine whether the particular one of the plurality of word lines is one of the plurality of predetermined open block read disturb trigger word lines. The control means performs the open block read disturb detection operation in response to the particular one of the plurality of word lines being the one of the plurality of predetermined open block read disturb trigger word lines. The control means is additionally configured to continue programming the memory cells of the particular one of the plurality of word lines in response to one of the data mismatch count not being greater than the predetermined mismatch threshold or the particular one of the plurality of word lines not being the one of the plurality of predetermined open block read disturb trigger word lines. The control means determines whether another of the plurality of word lines immediately above the particular one of the plurality of word lines vertically is one of the plurality of predetermined post-write read error trigger word lines. The control means is further configured to continue programming the memory cells of the particular one of the plurality of word lines in response to determining the another of the plurality of word lines is not one of the plurality of predetermined post-write read error trigger word lines. In addition, the control means is configured to start an enhanced post-write read error management operation in response to determining the another of the plurality of word lines is one of the plurality of predetermined post-write read error trigger word lines. The control means reads and counts a first failure bit count of the memory cells connected to the one of the plurality of predetermined post-write read error trigger word lines of the one of the plurality of blocks having the threshold voltage greater than a predetermined course post-write read threshold voltage plus an open block compensation amount in the enhanced post-write read error management operation. The control means is additionally configured to determine whether the first failure bit count is greater than a first predetermined failure count threshold in the enhanced post-write read error management operation. The control means continues programming the memory cells of the one of the plurality of blocks in response to the first failure bit count not being greater than the first predetermined failure count threshold. The control means is further configured to read and count a second failure bit count of the memory cells connected to the one of the plurality of predetermined post-write read error trigger word lines of the one of the plurality of blocks having the threshold voltage greater than a predetermined optimal post-write read threshold voltage in the enhanced post-write read error management operation in response to the first failure bit count being greater than the first predetermined failure count threshold. Additionally, the control means is configured to determine whether the second failure bit count is greater than a second predetermined failure count threshold in the enhanced post-write read error management operation. The control means continues programming the memory cells of the one of the plurality of blocks in response to the second failure bit count not being greater than the second predetermined failure count threshold. The control means is also configured to mark the one of the plurality of blocks as a bad block and stop programming the memory cells of the one of the plurality of blocks in response to the second failure bit count being greater than the second predetermined failure count threshold.

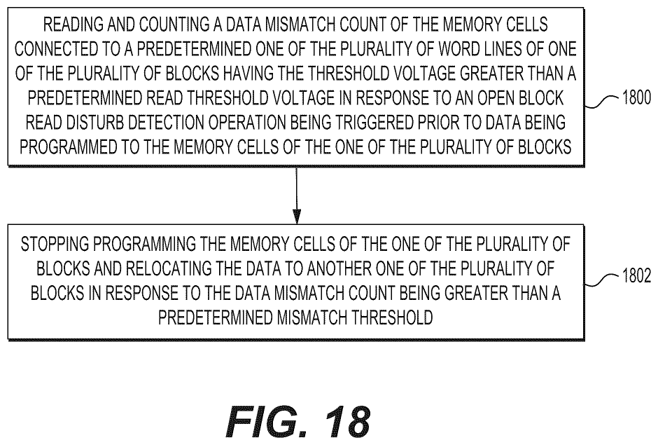

FIGS. 18-20 illustrate steps of a method of operating a memory apparatus. As discussed above, the memory apparatus (e.g., memory system 100 of FIG. 1A, memory die 300 of FIG. 2) includes memory cells (e.g., memory cells MC1, MC2, MC3 of FIG. 4E) each connected to one of a plurality of word lines (e.g., word line layers WLL0-WL127 in FIG. 4C) and disposed in memory holes (e.g., memory hole MH of FIG. 3, vertical columns 422, 432, 442, and 452 of FIGS. 4B-4C and 4E) each connected to one of a plurality of bit lines (e.g., bit line BL of FIG. 3, bit line 414 of FIG. 4C). The memory cells are configured to retain a threshold voltage corresponding to a plurality of data states (e.g., threshold voltage distributions shown in FIG. 5). The memory holes are grouped into a plurality of blocks (e.g., block 0-block M-1 of FIG. 4A). Referring initially to FIG. 18, the method includes the step of 1800 reading and counting a data mismatch count of the memory cells connected to a predetermined one of the plurality of word lines WORST RD WL of one of the plurality of blocks having the threshold voltage greater than a predetermined read threshold voltage in response to an open block read disturb detection operation being triggered prior to data being programmed to the memory cells of the one of the plurality of blocks. The method also includes the step of 1802 stopping programming the memory cells of the one of the plurality of blocks and relocating the data to another one of the plurality of blocks in response to the data mismatch count being greater than a predetermined mismatch threshold.

Again, according to an aspect, the predetermined one of the plurality of word lines WORST RD WL is known to exhibit worse read disturb than others of the plurality of word lines in other similar memory apparatuses. Also, as above and referring back to FIG. 17, the predetermined one of the plurality of word lines WORST RD WL is connected to ones of the memory cells that are erased.

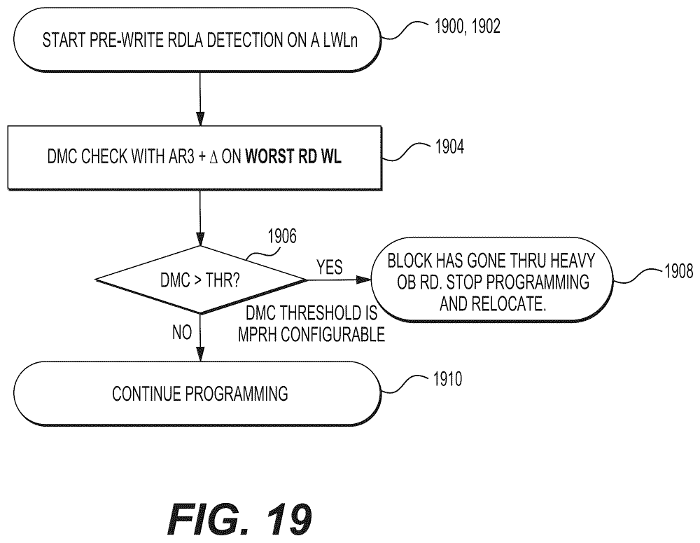

As discussed above, the plurality of word lines includes the plurality of predetermined open block read disturb trigger word lines (e.g., dashed vertical lines of top portion of FIG. 17). Thus, referring specifically to FIG. 19 and according to aspects of the disclosure, the method further includes the step of 1900 determining whether the memory cells being programmed are connected to one of the plurality of predetermined open block read disturb trigger word lines. The method also includes the step of 1902 determining the open block read disturb detection operation is triggered in response to determining the memory cells being programmed are connected to one of the plurality of predetermined open block read disturb trigger word lines.

Once again, the plurality of word lines (e.g., W in FIG. 3, word line layers WLL0-WL127 in FIG. 4C) and a plurality of dielectric layers (e.g., D in FIG. 3, dielectric layers DL0-DL141 of FIG. 4C) extend horizontally and overlay one another in an alternating fashion in a stack (e.g., memory structure 326 of FIG. 3). The memory holes (e.g., memory hole MH of FIG. 3, vertical columns 422, 432, 442, and 452 of FIGS. 4B-4C and 4E) extend vertically through the stack. The memory cells are connected in series between at least one drain-side select gate transistor (e.g., SGD0-SGD3 in FIG. 4C) on a drain-side of each of the memory holes and at least one source-side select gate transistor (e.g., SGS0-SGS3 in FIG. 4C) on a source-side of each of the memory holes. The at least one drain-side select gate transistor of each of the memory holes is coupled to one of a plurality of bit lines (e.g., bit line 414 of FIG. 4C) and the source-side select gate transistor of each of the memory holes is connected to a source line (e.g., source line SL of FIG. 4C). According to an aspect, the plurality of predetermined open block read disturb trigger word lines (e.g., dashed vertical lines of top portion of FIG. 17) are evenly spaced vertically. The predetermined one of the plurality of word lines WORST RD WL is vertically closer to a bottom of the stack than a top of the stack (see e.g., right hand side of blocks of FIG. 17).

As discussed and according to an aspect, each of the memory cells is configured to store three bits and threshold voltage corresponds to one of a plurality of data states. The plurality of data states includes, in order of the threshold voltage increasing in magnitude, an erased data state (e.g., S0 data state of FIG. 5), a first data state (e.g., S1 data state of FIG. 5), a second data state (e.g., S2 data state of FIG. 5), a third data state (e.g., S3 data state of FIG. 5), a fourth data state (e.g., S4 data state of FIG. 5), a fifth data state (e.g., S5 data state of FIG. 5), a sixth data state (e.g., S6 data state of FIG. 5), and a seventh data state (e.g., S7 data state of FIG. 5). The predetermined read threshold voltage is equal to a read compare voltage associated with the first data state plus a predetermined delta (i.e., AR3+Δ). Accordingly, referring back to FIG. 19, the method, as part of the pre-write open block read disturb detection operation, further includes the step of 1904 reading and counting the data mismatch count of the memory cells connected to the predetermined one of the plurality of word lines WORST RD WL of one of the plurality of blocks having the threshold voltage greater than the read compare voltage associated with the first data state plus the predetermined delta in response to the open block read disturb detection operation being triggered prior to data being programmed to the memory cells of the one of the plurality of blocks. The method continues with the step of 1906 determining whether the data mismatch count is greater than the predetermined mismatch threshold. The method additionally includes the step of 1908 stopping programming the memory cells of the one of the plurality of blocks and relocating the data to another one of the plurality of blocks in response to the data mismatch count being greater than the predetermined mismatch threshold. The method also includes the step of 1910 continuing programming the memory cells of the one of the plurality of blocks in response to the data mismatch count not being greater than the predetermined mismatch threshold.

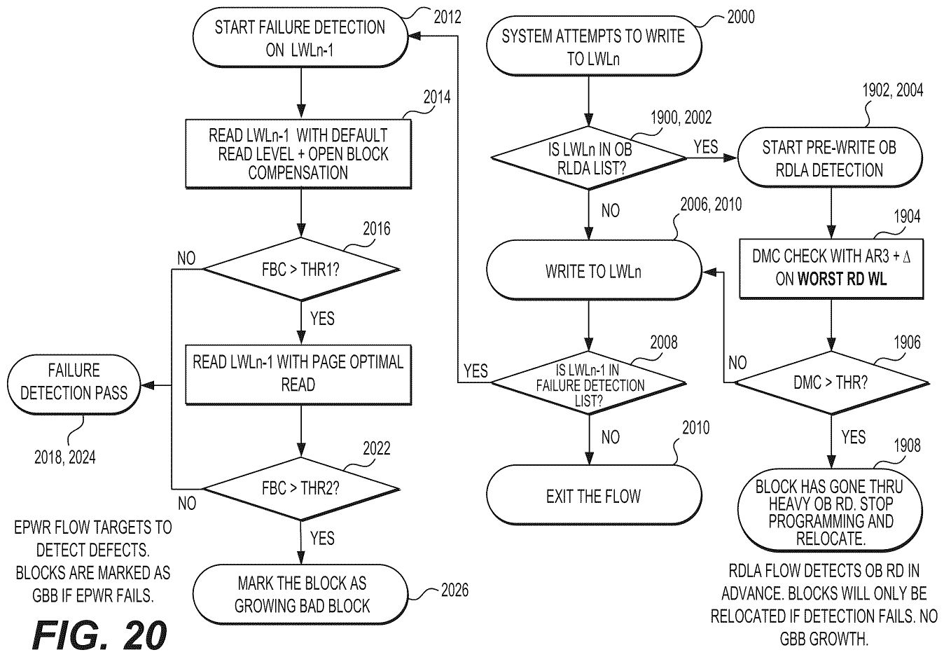

As mentioned above, the plurality of word lines includes a plurality of predetermined post-write read error trigger word lines. According to further aspects and now referring specifically to FIG. 20, the method further includes the step of 2000 beginning programming the memory cells of a particular one of the plurality of word lines. The method additionally includes the step of 2002 determining whether the particular one of the plurality of word lines is one of the plurality of predetermined open block read disturb trigger word lines. Next, 2004 performing the open block read disturb detection operation in response to the particular one of the plurality of word lines being the one of the plurality of predetermined open block read disturb trigger word lines. The method continues with the step of 2006 continuing programming the memory cells of the particular one of the plurality of word lines in response to one of the data mismatch count not being greater than the predetermined mismatch threshold or the particular one of the plurality of word lines not being the one of the plurality of predetermined open block read disturb trigger word lines. The method proceeds by 2008 determining whether another of the plurality of word lines immediately above the particular one of the plurality of word lines vertically is one of the plurality of predetermined post-write read error trigger word lines. The method additionally includes the step of 2010 continuing programming the memory cells of the particular one of the plurality of word lines in response to determining the another of the plurality of word lines is not one of the plurality of predetermined post-write read error trigger word lines. Next, 2012 starting an enhanced post-write read error management operation in response to determining the another of the plurality of word lines is one of the plurality of predetermined post-write read error trigger word lines. The method continues by 2014 reading and counting a first failure bit count of the memory cells connected to the one of the plurality of predetermined post-write read error trigger word lines of the one of the plurality of blocks having the threshold voltage greater than a predetermined course post-write read threshold voltage plus an open block compensation amount in the enhanced post-write read error management operation. The method further includes the step of 2016 determining whether the first failure bit count is greater than a first predetermined failure count threshold in the enhanced post-write read error management operation. The method proceeds with the step of 2018 continuing programming the memory cells of the one of the plurality of blocks in response to the first failure bit count not being greater than the first predetermined failure count threshold. The method additionally includes the step of 2020 reading and counting a second failure bit count of the memory cells connected to the one of the plurality of predetermined post-write read error trigger word lines of the one of the plurality of blocks having the threshold voltage greater than a predetermined optimal post-write read threshold voltage in the enhanced post-write read error management operation in response to the first failure bit count being greater than the first predetermined failure count threshold. Next, 2022 determining whether the second failure bit count is greater than a second predetermined failure count threshold in the enhanced post-write read error management operation. In addition, the method includes the step of 2024 continuing programming the memory cells of the one of the plurality of blocks in response to the second failure bit count not being greater than the second predetermined failure count threshold. The method also includes the step of 2026 marking the one of the plurality of blocks as a bad block and stopping programming the memory cells of the one of the plurality of blocks in response to the second failure bit count being greater than the second predetermined failure count threshold.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

What is claimed is:

1. A memory apparatus, comprising:
memory cells each connected to one of a plurality of word lines and disposed in memory holes and grouped into a plurality of blocks, the memory cells configured to retain a threshold voltage; and
a control means configured to:
read and count a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks, and
stop programming the memory cells of the one of the plurality of blocks and relocate the data to another one of the plurality of blocks in response to the data mismatch count being greater than a predetermined mismatch threshold.

2. The memory apparatus as set forth in claim 1, wherein the predetermined one of the plurality of word lines is known to exhibit worse read disturb than others of the plurality of word lines in other similar memory apparatuses.

3. The memory apparatus as set forth in claim 2, wherein the predetermined one of the plurality of word lines is connected to ones of the memory cells that are erased.

4. The memory apparatus as set forth in claim 1, wherein the plurality of word lines includes a plurality of predetermined open block read disturb trigger word lines and the control means is further configured to:
determine whether the memory cells being programmed are connected to one of the plurality of predetermined open block read disturb trigger word lines; and
determine the open block read disturb detection operation is triggered in response to determining the memory cells being programmed are connected to one of the plurality of predetermined open block read disturb trigger word lines.

5. The memory apparatus as set forth in claim 4, wherein the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the at least one drain-side select gate transistor of each of the memory holes is coupled to one of a plurality of bit lines and the source-side select gate transistor of each of the memory holes is connected to a source line, the plurality of predetermined open block read disturb trigger word lines are evenly spaced vertically, and the predetermined one of the plurality of word lines is vertically closer to a bottom of the stack than a top of the stack.

6. The memory apparatus as set forth in claim 5, wherein each of the memory cells is configured to store three bits and threshold voltage corresponds to one of a plurality of data states including, in order of the threshold voltage increasing in magnitude, an erased data state and a first data state and a second data state and a third data state and a fourth data state and a fifth data state and a sixth data state and a seventh data state, the predetermined read threshold voltage is equal to a read compare voltage associated with the first data state plus a predetermined delta, and the control means, as part of the open block read disturb detection operation, is further configured to:
read and count the data mismatch count of the memory cells connected to the predetermined one of the plurality of word lines of one of the plurality of blocks having the threshold voltage greater than the read compare voltage associated with the first data state plus the predetermined delta in response to the open block read disturb detection operation being triggered prior to data being programmed to the memory cells of the one of the plurality of blocks;
determine whether the data mismatch count is greater than the predetermined mismatch threshold;
stop programming the memory cells of the one of the plurality of blocks and relocate the data to another one of the plurality of blocks in response to the data mismatch count being greater than the predetermined mismatch threshold; and
continue programming the memory cells of the one of the plurality of blocks in response to the data mismatch count not being greater than the predetermined mismatch threshold.

7. The memory apparatus as set forth in claim 6, wherein the plurality of word lines includes a plurality of predetermined post-write read error trigger word lines and the control means is further configured to:
begin programming the memory cells of a particular one of the plurality of word lines;
determine whether the particular one of the plurality of word lines is one of the plurality of predetermined open block read disturb trigger word lines;
perform the open block read disturb detection operation in response to the particular one of the plurality of word lines being the one of the plurality of predetermined open block read disturb trigger word lines;
continue programming the memory cells of the particular one of the plurality of word lines in response to one of the data mismatch count not being greater than the predetermined mismatch threshold or the particular one of the plurality of word lines not being the one of the plurality of predetermined open block read disturb trigger word lines;
determine whether another of the plurality of word lines immediately above the particular one of the plurality of word lines vertically is one of the plurality of predetermined post-write read error trigger word lines;
continue programming the memory cells of the particular one of the plurality of word lines in response to determining the another of the plurality of word lines is not one of the plurality of predetermined post-write read error trigger word lines;
start an enhanced post-write read error management operation in response to determining the another of the plurality of word lines is one of the plurality of predetermined post-write read error trigger word lines;
read and count a first failure bit count of the memory cells connected to the one of the plurality of predetermined post-write read error trigger word lines of the one of the plurality of blocks having the threshold voltage greater than a predetermined course post-write read threshold voltage plus an open block compensation amount in the enhanced post-write read error management operation;
determine whether the first failure bit count is greater than a first predetermined failure count threshold in the enhanced post-write read error management operation;
continue programming the memory cells of the one of the plurality of blocks in response to the first failure bit count not being greater than the first predetermined failure count threshold;
read and count a second failure bit count of the memory cells connected to the one of the plurality of predetermined post-write read error trigger word lines of the one of the plurality of blocks having the threshold voltage greater than a predetermined optimal post-write read threshold voltage in the enhanced post-write read error management operation in response to the first failure bit count being greater than the first predetermined failure count threshold;
determine whether the second failure bit count is greater than a second predetermined failure count threshold in the enhanced post-write read error management operation;
continue programming the memory cells of the one of the plurality of blocks in response to the second failure bit count not being greater than the second predetermined failure count threshold; and
mark the one of the plurality of blocks as a bad block and stop programming the memory cells of the one of the plurality of blocks in response to the second failure bit count being greater than the second predetermined failure count threshold.

8. A controller in communication with a memory apparatus including memory cells each connected to one of a plurality of word lines and disposed in memory holes and grouped into a plurality of blocks, the memory cells configured to retain a threshold voltage, the controller configured to:
instruct the memory apparatus to read and count a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks; and
instruct the memory apparatus to stop programming the memory cells of the one of the plurality of blocks and relocate the data to another one of the plurality of blocks in response to the data mismatch count being greater than a predetermined mismatch threshold.

9. The controller as set forth in claim 8, wherein the predetermined one of the plurality of word lines is known to exhibit worse read disturb than others of the plurality of word lines in other similar memory apparatuses.

10. The controller as set forth in claim 9, wherein the predetermined one of the plurality of word lines is connected to ones of the memory cells that are erased.

11. The controller as set forth in claim 8, wherein the plurality of word lines includes a plurality of predetermined open block read disturb trigger word lines and the controller is further configured to:
determine whether the memory cells being programmed are connected to one of the plurality of predetermined open block read disturb trigger word lines; and
determine the open block read disturb detection operation is triggered in response to determining the memory cells being programmed are connected to one of the plurality of predetermined open block read disturb trigger word lines.

12. The controller as set forth in claim 11, wherein the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the at least one drain-side select gate transistor of each of the memory holes is coupled to one of the plurality of bit lines and the source-side select gate transistor of each of the memory holes is connected to a source line, the plurality of predetermined open block read disturb trigger word lines are evenly spaced vertically, and the predetermined one of the plurality of word lines is vertically closer to a bottom of the stack than a top of the stack.

13. The controller as set forth in claim 12, wherein each of the memory cells is configured to store three bits and threshold voltage corresponds to one of a plurality of data states including, in order of the threshold voltage increasing in magnitude, an erased data state and a first data state and a second data state and a third data state and a fourth data state and a fifth data state and a sixth data state and a seventh data state, the predetermined read threshold voltage is equal to a read compare voltage associated with the first data state plus a predetermined delta, and the controller, as part of the open block read disturb detection operation, is further configured to:
instruct the memory apparatus to read and count the data mismatch count of the memory cells connected to the predetermined one of the plurality of word lines of one of the plurality of blocks having the threshold voltage greater than the read compare voltage associated with the first data state plus the predetermined delta in response to the open block read disturb detection operation being triggered prior to data being programmed to the memory cells of the one of the plurality of blocks;
determine whether the data mismatch count is greater than the predetermined mismatch threshold;
instruct the memory apparatus to stop programming the memory cells of the one of the plurality of blocks and relocate the data to another one of the plurality of blocks in response to the data mismatch count being greater than the predetermined mismatch threshold; and
instruct the memory apparatus to continue programming the memory cells of the one of the plurality of blocks in response to the data mismatch count not being greater than the predetermined mismatch threshold.

14. A method of operating a memory apparatus including memory cells each connected to one of a plurality of word lines and disposed in memory holes and grouped into a plurality of blocks, the memory cells configured to retain a threshold voltage, the method comprising the steps of:
reading and counting a data mismatch count of the memory cells connected to a predetermined one of the plurality of word lines of one of the plurality of blocks having the threshold voltage greater than a predetermined read threshold voltage in response to an open block read disturb detection operation being triggered prior to data being programmed to the memory cells of the one of the plurality of blocks; and
stopping programming the memory cells of the one of the plurality of blocks and relocating the data to another one of the plurality of blocks in response to the data mismatch count being greater than a predetermined mismatch threshold.

15. The method as set forth in claim 14, wherein the predetermined one of the plurality of word lines is known to exhibit worse read disturb than others of the plurality of word lines in other similar memory apparatuses.

16. The method as set forth in claim 15, wherein the predetermined one of the plurality of word lines is connected to ones of the memory cells that are erased.

17. The method as set forth in claim 14, wherein the plurality of word lines includes a plurality of predetermined open block read disturb trigger word lines and the method further includes the steps of:
determining whether the memory cells being programmed are connected to one of the plurality of predetermined open block read disturb trigger word lines; and
determining the open block read disturb detection operation is triggered in response to determining the memory cells being programmed are connected to one of the plurality of predetermined open block read disturb trigger word lines.

18. The method as set forth in claim 17, wherein the plurality of word lines and a plurality of dielectric layers extend horizontally and overlay one another in an alternating fashion in a stack, the memory holes extend vertically through the stack, the memory cells are connected in series between at least one drain-side select gate transistor on a drain-side of each of the memory holes and at least one source-side select gate transistor on a source-side of each of the memory holes, the at least one drain-side select gate transistor of each of the memory holes is coupled to one of the plurality of bit lines and the source-side select gate transistor of each of the memory holes is connected to a source line, the plurality of predetermined open block read disturb trigger word lines are evenly spaced vertically, and the predetermined one of the plurality of word lines is vertically closer to a bottom of the stack than a top of the stack.

19. The method as set forth in claim 18, wherein each of the memory cells is configured to store three bits and threshold voltage corresponds to one of a plurality of data states including, in order of the threshold voltage increasing in magnitude, an erased data state and a first data state and a second data state and a third data state and a fourth data state and a fifth data state and a sixth data state and a seventh data state, the predetermined read threshold voltage is equal to a read compare voltage associated with the first data state plus a predetermined delta, and the method, as part of a pre-write open block read disturb detection operation, further includes the steps of:
reading and counting the data mismatch count of the memory cells connected to the predetermined one of the plurality of word lines of one of the plurality of blocks having the threshold voltage greater than the read compare voltage associated with the first data state plus the predetermined delta in response to the open block read disturb detection operation being triggered prior to data being programmed to the memory cells of the one of the plurality of blocks;
determining whether the data mismatch count is greater than the predetermined mismatch threshold;
stopping programming the memory cells of the one of the plurality of blocks and relocating the data to another one of the plurality of blocks in response to the data mismatch count being greater than the predetermined mismatch threshold; and
continuing programming the memory cells of the one of the plurality of blocks in response to the data mismatch count not being greater than the predetermined mismatch threshold.

20. The method as set forth in claim 19, wherein the plurality of word lines includes a plurality of predetermined post-write read error trigger word lines and the method further includes the steps of:
beginning programming the memory cells of a particular one of the plurality of word lines;
determining whether the particular one of the plurality of word lines is one of the plurality of predetermined open block read disturb trigger word lines;
performing the open block read disturb detection operation in response to the particular one of the plurality of word lines being the one of the plurality of predetermined open block read disturb trigger word lines;
continuing programming the memory cells of the particular one of the plurality of word lines in response to one of the data mismatch count not being greater than the predetermined mismatch threshold or the particular one of the plurality of word lines not being the one of the plurality of predetermined open block read disturb trigger word lines;
determining whether another of the plurality of word lines immediately above the particular one of the plurality of word lines vertically is one of the plurality of predetermined post-write read error trigger word lines;
continuing programming the memory cells of the particular one of the plurality of word lines in response to determining the another of the plurality of word lines is not one of the plurality of predetermined post-write read error trigger word lines;
starting an enhanced post-write read error management operation in response to determining the another of the plurality of word lines is one of the plurality of predetermined post-write read error trigger word lines;
reading and counting a first failure bit count of the memory cells connected to the one of the plurality of predetermined post-write read error trigger word lines of the one of the plurality of blocks having the threshold voltage greater than a predetermined course post-write read threshold voltage plus an open block compensation amount in the enhanced post-write read error management operation;
determining whether the first failure bit count is greater than a first predetermined failure count threshold in the enhanced post-write read error management operation;
continuing programming the memory cells of the one of the plurality of blocks in response to the first failure bit count not being greater than the first predetermined failure count threshold;
reading and counting a second failure bit count of the memory cells connected to the one of the plurality of predetermined post-write read error trigger word lines of the one of the plurality of blocks having the threshold voltage greater than a predetermined optimal post-write read threshold voltage in the enhanced post-write read error management operation in response to the first failure bit count being greater than the first predetermined failure count threshold;
determining whether the second failure bit count is greater than a second predetermined failure count threshold in the enhanced post-write read error management operation;
continuing programming the memory cells of the one of the plurality of blocks in response to the second failure bit count not being greater than the second predetermined failure count threshold; and
marking the one of the plurality of blocks as a bad block and stopping programming the memory cells of the one of the plurality of blocks in response to the second failure bit count being greater than the second predetermined failure count threshold.
